(19) United States
(12) Patent Application Publication
(10) Pub. No.: US 2012/0325319 A1
(43) Pub. Date: Dec. 27, 2012

(54) PHOTOELECTRIC CONVERSION ELEMENT, METHOD FOR PRODUCING PHOTOELECTRIC CONVERSION ELEMENT AND SOLAR CELL

(75) Inventors: Kazukuni NISHIMURA, Tokyo (JP); Kenichi ONAKA, Tokyo (JP); Kazuya ISOBE, Tokyo (JP)

(73) Assignee: KONICA MINOLTA BUSINESS TECHNOLOGIES, INC., Tokyo (JP)

(21) Appl. No.: 13/494,209

(22) Filed: Jun. 12, 2012

(30) Foreign Application Priority Data
Jun. 23, 2011 (JP) JP2011-139792

(51) Int. Cl. H01L 51/46; H01L 51/48

(52) U.S. Cl. 136/263; 438/93; 257/E51.026

(57) ABSTRACT

A photoelectric conversion element excellent in photoelectric conversion efficiency and stability of photoelectric conversion function, a method for producing the photoelectric conversion element, and a solar cell comprising the photoelectric conversion element are provided. The present invention relates to a photoelectric conversion element comprising a substrate, a first electrode, a photoelectric conversion layer containing a semiconductor and a sensitizing dye, and a hole transport layer, and a second electrode, wherein the hole transport layer comprises a polymer having a repeating unit represented by the general formula (1) or (2), and the sensitizing dye is represented by any of the general formulas (3A) to (3C).

### CROSS-REFERENCE TO RELATED APPLICATION

This application is based on Japanese Patent Application No. 2011-139792 filed on Jun. 23, 2011, the contents of which are incorporated herein by reference.

### BACKGROUND

1. Technical Field

The present invention relates to a dye sensitizing type photoelectric conversion element, a method for producing the photoelectric conversion element and a solar cell that is constituted with the photoelectric conversion element.

2. Description of Related Arts

In recent years, solar light energy has been drawn attention as an energy source in terms of environmental problems, a method of converting light and heat by solar light energy into electric energy as a more usable energy form has been put into practical use. In particular, a method of converting solar light into electric energy is typical, and a photoelectric conversion element is used in this method. For the photoelectric conversion element, a photoelectric conversion element using an inorganic material such as single crystal silicon, polycrystal silicon, amorphous silicon, cadmium telluride and copper indium selenide has been widely used for, so-called, a solar cell. A solar cell obtained by using a photoelectric conversion element using these inorganic materials has a multilayer pn junction structure in which a silicon, or the like used as a material is required to be a high purity product obtained by undergoing a high purification process, and thus, there has been problems such that production steps are complicated and the number of processes is large, and a production cost is high.

On the other hand, researches of a photoelectric conversion element using an organic material as a simpler element have progressed. For example, pn junction type organic photoelectric conversion element obtained by connecting a perylenetetracarboxylic acid derivative as an n-type organic dye and copper phthalocyanine as a p-type organic dye has been reported. In order to improve a short exciter diffusion length and a thin space charge layer, which are considered to be defective points in an organic photoelectric conversion element, an attempt to simply increase an area of pn junction portion to which organic thin films are laminated to ensure a sufficient number of organic dyes involved in charge separation has been achieving results.

Further, there has been a technique in which a pn junction portion is significantly increased by complexing an n-type electron conductive organic material and a p-type hole conductive polymer in a film to carry out charge separation in the entire film, for example. Heeger, et al. suggested in 1995 a photoelectric conversion element obtained by mixing a conjugate polymer as a p-type conductive polymer and fullerene as an electron conductive material.

Although the photoelectric conversion element has gradually attained improved characteristics thereof, it has not been able to operate stably with keeping high conversion efficiency.

However, in 1991, Gratzel performed huge and detailed experiments of a sensitizing photoelectric current of a dye adsorbed on titanium oxide, to succeed in preparation of a photoelectric conversion element that operates stably and has high conversion efficiency by forming titanium oxide into being porous, and sufficiently securing a charge separation area (the number of molecules contributing to charge separation) (for example, see B. O'Regan and M. Gratzel: Nature, 353, 737 (1991)).

In this photoelectric conversion element, cycles in which a dye adsorbed on a surface of porous titanium oxide is photoexcited, electrons are injected into titanium oxide from the dye to form a dye cation, and the dye receives electrons through a hole transport layer from a counter electrode are repeated. For the hole transport layer, an electrolytic solution obtained by dissolving electrolyte containing iodine into an organic solvent has been used. This photoelectric conversion element has excellent reproducibility in cooperation with stability of titanium oxide, bases of research and development have been largely extended, and this photoelectric conversion element is also called a dye-sensitized solar cell, which receives high expectation and attention. In this method, an inexpensive metal compound semiconductor such as titanium oxide is not required to be purified to high purity, an inexpensive one can be used as the semiconductor, further, available light ranges over the wide visible light region, and this method has an advantage such that the solar light having many visible light components can be effectively converted into electricity. However, since a ruthenium complex having restriction as the resource is used for a photoelectric conversion layer, there are problems such that an expensive ruthenium complex is required to be used, stability with time is not sufficient, and the like. In addition, as a further problem, a dye-sensitized solar cell operates using an electrolytic solution as described above and thus had a problem of requiring another mechanism to prevent retention, and effluence and dissipation of the electrolytic solution and iodine.

Typical examples of other electrochemical elements having an electrolytic solution include a lead storage battery and a lithium battery. Even these electrochemical elements, which are formed into compact modules, are not recovered at 100% to be recycled, and when dissipated chemical species are accumulated in an environment, it is apparent to cause secondary problems.

Development of an all solid-state dye-sensitized solar cell that avoids such problems of an electrolytic solution and takes over advantages of a dye-sensitized solar cell has been also progressing.

In this field, all solid-state dye sensitizing type solar cells using an amorphous organic hole transport agent and using copper iodide as a hole transport agent have been known. Since conductivity of a hole transport agent is low, however, such cells have not yet attained sufficient photoelectric conversion efficiency.

Typical examples of a hole transport agent having comparatively high conductivity include polythiophene-based materials, and an all solid-state dye-sensitized solar cell using PEDOT as a hole transport agent has been reported (for example, see J. Xia, N. Masaki, M. Lira-Cantu, Y. Kim, K. Jiang and S. Yanagida: Journal of the American Chemical Society, 130, 1258 (2008)). However, since PEDOT has absorption in the visible light region (400 to 700 nm), loss for light absorption of a dye is generated, and photoelectric conversion efficiency has not been sufficient yet.

On the other hand, it was reported that when the PEDOT substituent described in L. Groenendaal, G. Zotti and F. Joans, Synthetic Metals, 118, 105 (2001) is used, absorbance in the visible light region is reduced while maintaining conductivity, and an all solid-state dye-sensitized solar cell using the PEDOT substituent as a hole transport agent has been also reported (for example, see JP-A-2000-106223).

### SUMMARY

However, in the dye sensitizing type solar cells described in L. Groenendaal, G. Zotti and F. Joans, Synthetic. Metals, 118, 105 (2001) and JP-A-2000-106223, a ruthenium metal complex dye is mainly used as a sensitizing dye, and since the ruthenium metal complex dye has a small molar extinction coefficient, a porous titanium oxide layer is required to have a film thickness of about 10 μm and a hole transport layer is also required to have a film thickness of about 10 μm, in order to sufficiently absorb incident light. Even if the above-mentioned PEDOT substitution is used, loss for photoelectric conversion due to its absorption of visible light cannot be avoided with this film thickness. Accordingly, an all solid-state dye-sensitized solar cell which can sufficiently absorb incident light with a thinner film thickness is desired.

The present invention was made in view of the above described problems, and an object thereof is to provide a photoelectric conversion element excellent in photoelectric conversion efficiency and stability of photoelectric conversion function, in particular, an all solid-state dye sensitizing type photoelectric conversion element, a method for producing the photoelectric conversion element and a solar cell.

The present inventors have performed intensive studies in order to improve the above problems, to reach an opinion that it is necessary to develop a novel hole transport agent having high conductivity and no absorption in visible light region, and a novel sensitizing dye having a large molar extinction coefficient which can absorb visible light with a wide range of wavelengths in a small amount. As a result of seeking possibility of various novel materials, the present inventors have found combination of a polymer hole transport agent having a specific structure and a sensitizing dye suitable for the hole transport agent, and completed the present invention.

To achieve at least one of the abovementioned objects, a photoelectric conversion element reflecting one aspect of the present invention comprises a substrate, a first electrode, a photoelectric conversion layer containing a semiconductor and a sensitizing dye, and a hole transport layer, and a second electrode,

wherein the hole transport layer comprises a polymer having a repeating unit (1) represented by the following general formula (1):

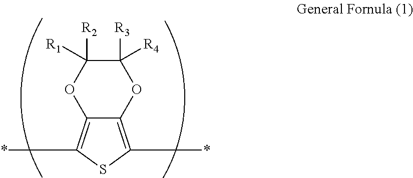

wherein R₁ to R₄ each independently represent a hydrogen atom, a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, provided that at least one of R₁ to R₄ is a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, and the remaining substituents are hydrogen atoms,

or a repeating unit (2) represented by the following general formula (2):

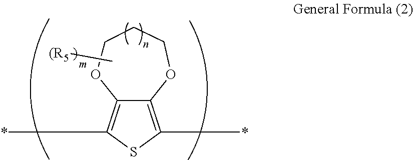

wherein R₅ each independently represents a halogen atom, a linear or branched alkyl group having 1 to 24 carbon atoms, or an alkoxy group having 1 to 18 carbon atoms, n is an integer from 1 to 3, and m is an integer from 0 to 2n+4, and

the sensitizing dye is represented by the following general formula (3A), (3B) or (3C):

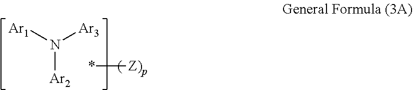

wherein Ar₁ to Ar₃ each independently represent an aromatic group, provided that any two of Ar₁ to Ar₃ may bond each other to form a ring structure, Z represents a group having an acidic group and an electron-attracting group or a group having an acidic group and an electron-attracting ring structure, which is substituted in any of Ar₁ to Ar₃, and p is an integer from 1 to 3,

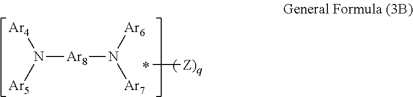

wherein Ar₄ to Ar₇ each independently represent an aromatic group, provided that Ar₄ and Ar₅ or Ar₆ and Ar₇ may bond each other to form a ring structure, Ar₈ represents a divalent aromatic group, Z represents a group having an acidic group and an electron-attracting group or a group having an acidic group and an electron-attracting ring structure, which is substituted in any of Ar₄ to Ar₇, and q is an integer from 1 to 4,

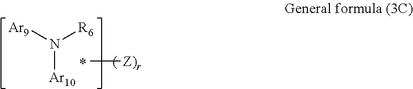

wherein Ar₉ and Ar₁₀ each independently represent an aromatic group, R₆ represents a linear or branched alkyl group having 1 to 24 carbon atoms, or a cycloalkyl group having 3 to 9 carbon atoms, provided that Ar₉ and Ar₁₀, or Ar₉ or Ar₁₀ and R₆ may bond each other to form a ring structure, Z represents a group having an acidic group and an electron-attracting group or a group having an acidic group and an electron-attracting ring structure, which is substituted in any of Ar₉, Ar₁₀ and R₆, and r is an integer of 1 to 2.

The objects, features, and characteristics of this invention other than those set forth above will become apparent from the description given herein below with reference to preferred embodiments illustrated in the accompanying drawings.

### BRIEF DESCRIPTION OF THE DRAWINGS

FIG. 1 is a schematic sectional view showing an embodiment of the photoelectric conversion element of the present invention. In the FIG. 1, symbol 1 stands for a substrate; 2 for a first electrode; 3 for a barrier layer; 4 for a sensitizing dye; 5 for a semiconductor; 6 for a photoelectric conversion layer; 7 for a hole transport layer; 8 for a second electrode; 9 for an incidence direction of solar light; and 10 for a photoelectric conversion element.

### DETAILED DESCRIPTION

The present invention provides a photoelectric conversion element comprising a substrate, a first electrode, a photoelectric conversion layer containing a semiconductor and a sensitizing dye, and a hole transport layer, and a second electrode,

wherein the hole transport layer comprises a polymer having a repeating unit (1) represented by the above general formula (1) or a repeating unit (2) represented by the above general formula (2), and the sensitizing dye is represented by the above general formula (3A), general formula (3B) or general formula (3C). The present invention has a feature in using the polymer having a specific repeating unit in the hole transport layer, and using the dye having the specific structure as the sensitizing dye. By such a specific combination, absorbance of the hole transport layer within visible light region (400 to 700 nm) can be reduced, and thus, a photoelectric conversion element and a solar cell, which are excellent in photoelectric conversion efficiency and stability of photoelectric conversion functions, can be provided.

Hereinafter, the present invention will be specifically described.

(Photoelectric Conversion Element)

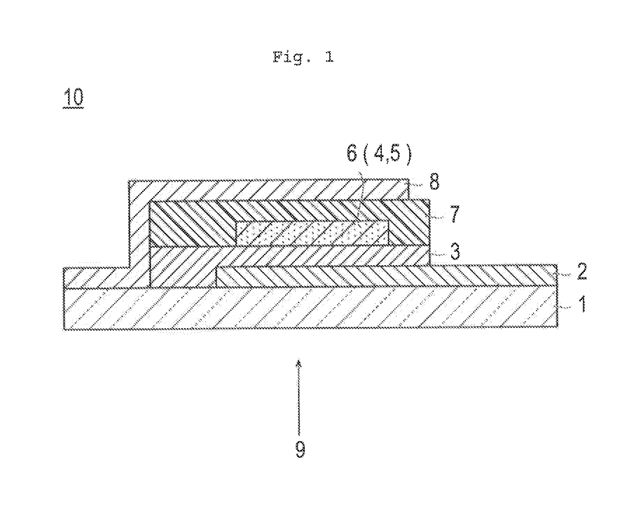

The photoelectric conversion element of the present invention is described with reference to FIG. 1.

FIG. 1 is a schematic sectional view showing an embodiment of the photoelectric conversion element of the present invention. As shown in FIG. 1, a photoelectric conversion element 10 is constituted with a substrate 1, a first electrode 2, a photoelectric conversion layer 6, a hole transport layer 7, a second electrode 8, and a barrier layer 3. The photoelectric conversion layer 6 comprises a semiconductor 5 and a sensitizing dye 4. As shown in FIG. 1, the barrier layer 3 is preferably provided between the first electrode 2 and the photoelectric conversion layer 6 for the purpose of prevention of short circuit, sealing, and the like. Note that although solar light enters in the direction of arrow 9 from the lower side in FIG. 1, the present invention is not limited to this embodiment, and solar light may enter from the upper side.

Then, a preferable embodiment of a method for producing the photoelectric conversion element of the present invention will be described below.

The barrier layer 3 is attached and formed on the substrate 1 forming the first electrode 2 thereon. A semiconductor layer made of the semiconductor 5 is then formed on the barrier layer 3, and the sensitizing dye 4 is adsorbed to the surface of the semiconductor to form the photoelectric conversion layer 6. Subsequently, the hole transport layer 7 is formed on the photoelectric conversion layer 6. Further, the hole transport layer 7 intrudes into the photoelectric conversion layer 6 made of the semiconductor 5 supporting the sensitizing dye 4 and is present thereon, and the second electrode 8 is formed on the hole transport layer 7. Electric current can be taken out by attaching terminals to the first electrode 2 and the second electrode 8.

Hereinafter, each members of the photoelectric conversion element of the present invention will be described.

(Hole Transport Layer)

A hole transport layer is a layer which serves to rapidly reduce an oxidant of a sensitizing dye after absorbing light and injecting electrons into a semiconductor and to transport holes injected in the interface with the dye to a second electrode.

The hole transport layer contains a polymer having the repeating unit (1) represented by the following general formula (1) (hereinafter, also simply referred to as “the repeating unit (1)”) or the repeating unit (2) represented by the following general formula (2) (hereinafter, also simply referred to as “the repeating unit (2)”)

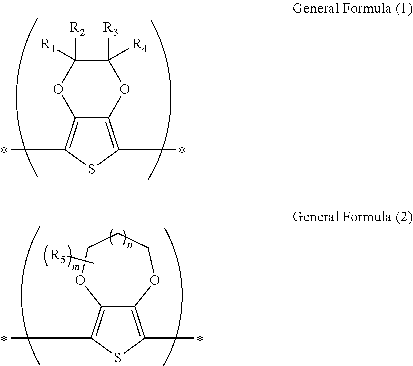

In the general formula (1), R₁ to R₄ each represents a hydrogen atom, a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group. R₁ to R₄ may be the same or different each other. In this condition, at least one of R₁ to R₄ is a linear or branched alkyl group having 1 to 24 carbon atoms, a cycloalkyl group having 3 to 9 carbon atoms, an alkoxy group having 1 to 18 carbon atoms, a polyethylene oxide group having 2 to carbon atoms, or an aryl group, and the remaining substituents are hydrogen atoms. Herein, combination of introduction of a hydrogen atom, and a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group (hereinafter, also referred to as “a substituent other than a hydrogen atom”) among R₁ to R₄ is not particularly limited, and any of the following combinations may be selected: (i) any one of R₁ to R₄ is a substituent other than a hydrogen atom, and the remaining substituents are hydrogen atoms; (ii) R₁ and R₂ are a substituent other than a hydrogen atom, and the remaining substituents are hydrogen atoms; (iii) R₁ and R₃ are a substituent other than a hydrogen atom, and the remaining substituents are hydrogen atoms; (iv) R₁, R₂ and R₃ are a substituent other than a hydrogen atom, and the remaining substituent is a hydrogen atom; and (v) all of R₁ to R₄ are a substituent other than a hydrogen atom. Among these, (i) and (iii) are preferable, and (i) is more preferable. A polymer having such a repeating unit (1) is preferable in view of its low absorbance within visible light region (400 to 700 nm), and high electrical conductivity. Note that carbon atoms to which substituents R₁ to R₄ are bound may be an asymmetric atom, which may be either of a chiral form or a racemic form.

The linear or branched alkyl group having 1 to 24 carbon atoms for R₁ to R₄ is not particularly limited. Examples thereof include methyl group, ethyl group, n-propyl group, isopropyl group, n-butyl group, isobutyl group, sec-butyl group, tert-butyl group, n-pentyl group, isopentyl group, tert-pentyl group, neopentyl group, 1,2-dimethylpropyl group, n-hexyl group, isohexyl group, 1,3-dimethylbutyl group, 1-isopropylpropyl group, 1,2-dimethylbutyl group, n-heptyl group, 1,4-dimethylpentyl group, 3-ethylpentyl group, 2-methyl-1-isopropylpropyl group, 1-ethyl-3-methylbutyl group, n-octyl group, 2-ethylhexyl group, 3-methyl-1-isopropylbutyl group, 2-methyl-1-isopropyl group, 1-t-butyl-2-methylpropyl group, n-nonyl group, 3,5,5-trimethylhexyl group, n-decyl group, isodecyl group, n-undecyl group, 1-methyldecyl group, n-dodecyl group, n-tridecyl group, n-tetradecyl group, n-pentadecyl group, n-hexadecyl group, n-heptadecyl group, n-octadecyl group, n-nonadecyl group, n-eicosyl group, n-heneicosyl group, n-docosyl group, n-tricosyl group, and n-tetracosyl group. Among these groups, a linear or branched alkyl group having 6 to 18 carbon atoms is preferable, and a linear alkyl group having 6 to 18 carbon atoms is more preferable. It is further more preferable that only R₁ is a linear alkyl group having 6 to 18 carbon atoms, and all of R₂, R₃ and R₄ are hydrogen atoms.

The cycloalkyl group having 3 to 9 carbon atoms for R₁ to R₄ is not particularly limited. Examples thereof include cyclopropyl group, cyclobutyl group, cyclopentyl group, cyclohexyl group, cycloheptyl group, cyclooctyl group, and cyclononyl group. Among these groups, a cycloalkyl group having 3 to 6 carbon atoms is preferable.

The alkoxy group having 1 to 18 carbon atoms for R₁ to R₄ is not particularly limited. Examples thereof include methoxy group, ethoxy group, propoxy group, isopropoxy group, butoxy group, pentyloxy group, hexyloxy group, 2-ethylhexyloxy group, octyloxy group, nonyloxy group, decyloxy group, undecyloxy group, dodecyloxy group, tridecyloxy group, tetradecyloxy group, pentadecyloxy group, hexadecyloxy group, heptadecyloxy group, and octadecyloxy group. Among these groups, an alkoxy group having 6 to 18 carbon atoms is preferable, and a decyloxy group is more preferable.

The polyethylene oxide group having 2 to 18 carbon atoms for R₁ to R₄ is a group represented by the formula: —(CH₂CH₂O)ₓH or the formula: —(OCH₂CH₂)ₓH [wherein, x is an integer from 1 to 9]. Among these groups, a group in which x is 3 to 9 is preferable, and —(OCH₂CH₂)₉H is more preferable.

The aryl group for R₁ to R₄ is not particularly limited. Examples thereof include phenyl group, naphthyl group, biphenyl group, fluorenyl group, anthryl group, pyrenyl group, azulenyl group, acenaphthylenyl group, terphenyl group, and phenanthryl group. Among these groups, a phenyl group and a biphenyl group are preferable, and a phenyl group is more preferable.

That is, preferable examples of the repeating unit (1) include repeating units derived from the following compounds (M1-1) to (M1-22):

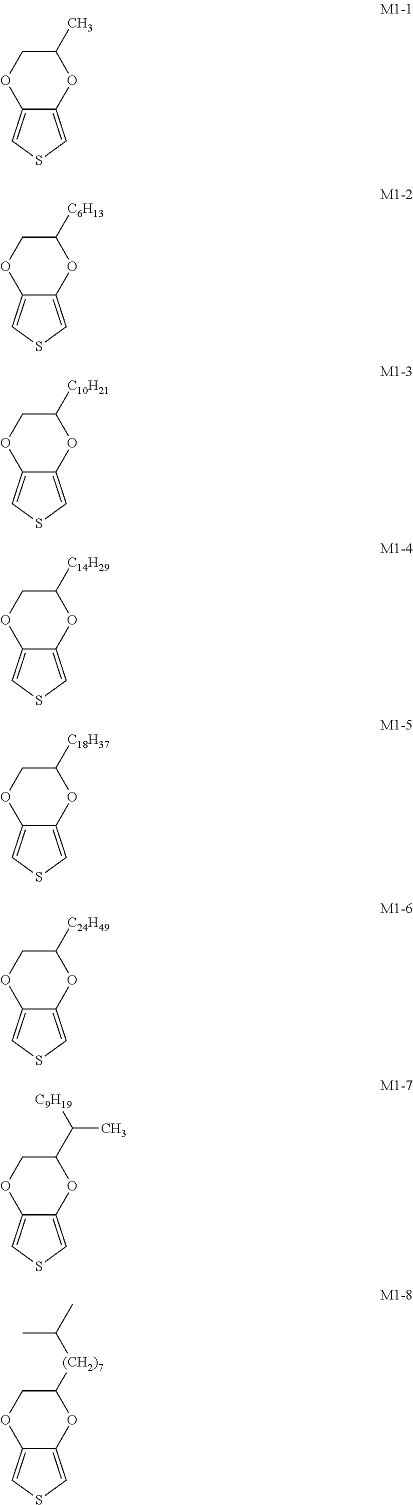

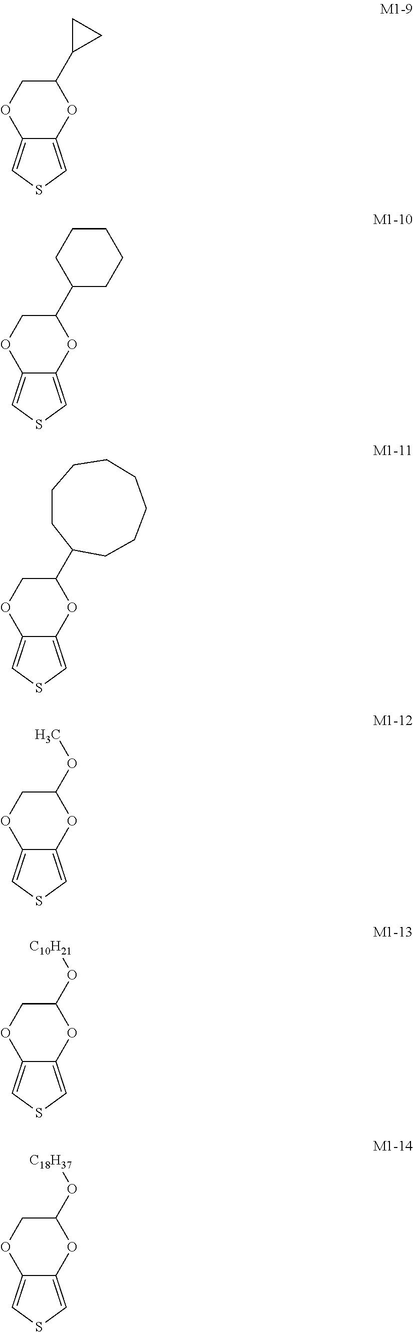

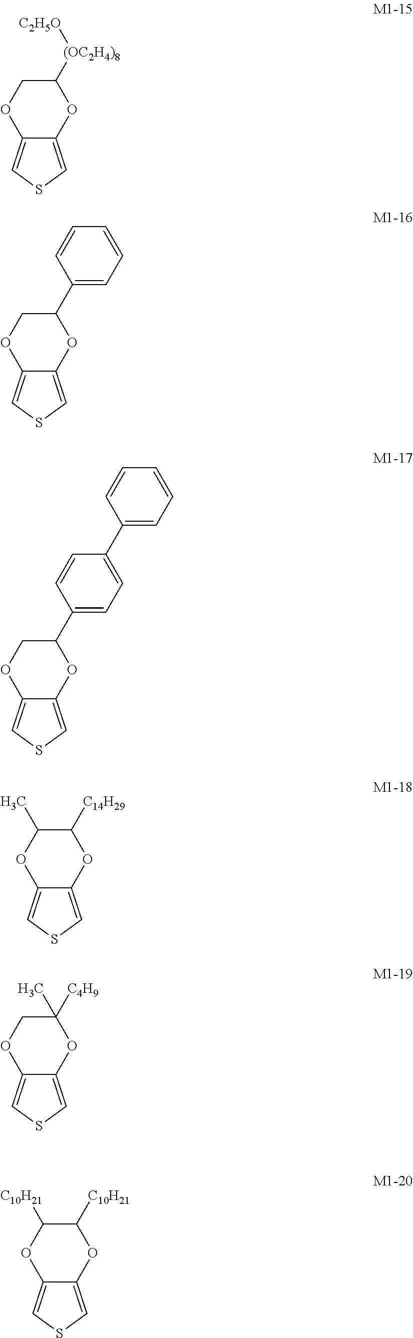

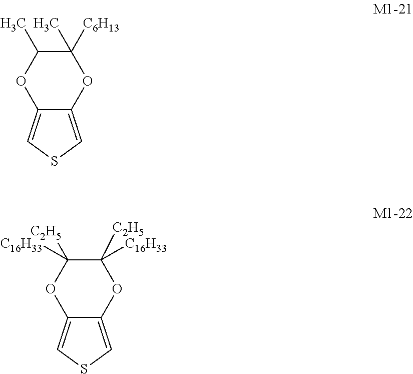

R₅ in the general formula (2) represents a halogen atom, a linear or branched alkyl group having 1 to 24 carbon atoms, or an alkoxy group having 1 to 18 carbon atoms. Note that when R₅ exists in the plural number (that is, m is an integer of 2 or more), each R₅ may be the same or different each other. A bond position of R₅ is not particularly limited. For example, when n is 1, R₅ may be introduced into position 1 or 2, and is preferably introduced into at least position 2. When n is 2, R₅ may be introduced into any of positions 1, 2 and 3, and is preferably introduced into position 2 or 3. A polymer having such a repeating unit (2) is preferable in view of its low absorbance within visible light region (400 to 700 nm), and high electrical conductivity.

The halogen atom for R₅ is not particularly limited, and may be any of a fluorine atom, a chlorine atom, a bromine atom, and an iodine atom. A chlorine atom and a fluorine atom are preferable, and a chlorine atom is more preferable. The linear or branched alkyl group having 1 to 24 carbon atoms for R₅ is not particularly limited, and may be specifically the same as the alkyl group defined in the general formula (1). A methyl group, ethyl group, n-propyl group, n-butyl group, n-pentyl group, and n-hexyl group are preferable, and a methyl group, ethyl group and n-butyl group are more preferable. Further, the alkoxy group having 1 to 18 carbon atoms for R₅ is not particularly limited, and may be specifically the same as the alkoxy group defined in the general formula (1). Alkoxy groups having 6 to 18 carbon atoms are preferable, and an octyloxy group is more preferable.

In the general formula (2), n is an integer from 1 to 3. n is preferably 1 or 2, and is particularly preferably 1. m is an integer from 0 to 2n+4. Herein, m of 0 means that R₅ does not exist, that is, every R₅ is a hydrogen atom. in is preferably 0 or 1 to 6, and m is more preferably 0 or 1 to 2.

That is, preferable examples of the repeating unit (2) include repeating units derived from the following compounds (M2-1) to (M2-10):

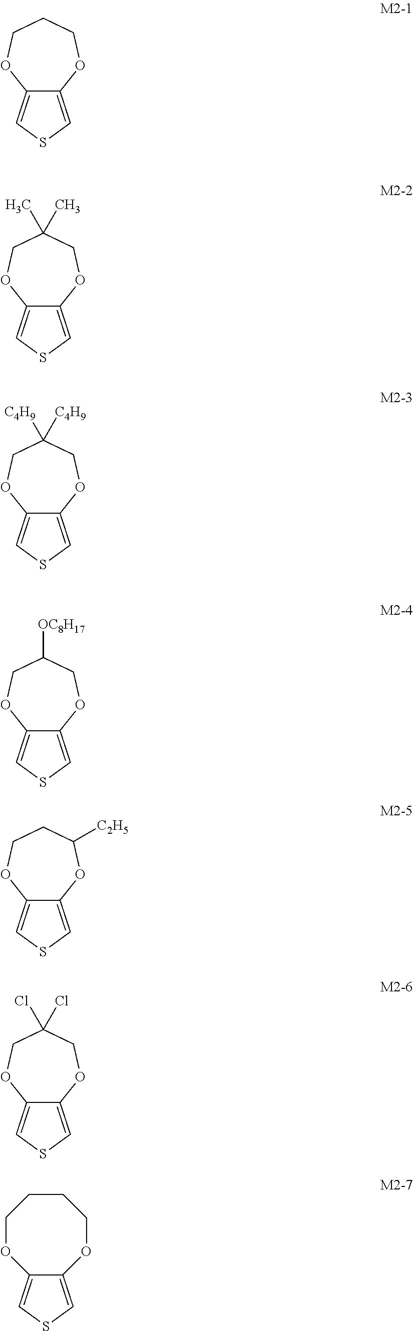

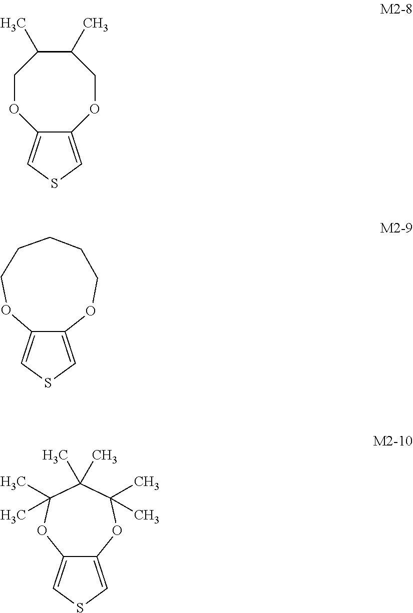

The polymer according to the present invention has the repeating unit (1) represented by the general formula (1) or the repeating unit (2) represented by the general formula (2). Note that a terminal of the polymer according to the present invention is not particularly limited, and can suitably be defined depending on kinds of raw materials to be used (such as a monomer, dimer, and multimer), and is generally a hydrogen atom. Herein, the polymer according to the present invention may be (a) constituted only with the repeating unit (1); (b) constituted only with the repeating unit (2); (c) constituted with the repeating unit (1) and the repeating unit (2); (d) constituted with the repeating unit (1) and a repeating unit of another monomer; (e) constituted with the repeating unit (2) and a repeating unit of another monomer; or (f) constituted with the repeating units (1) and (2) and a repeating unit of another monomer. The polymer according to the present invention is preferably (a), (b) or (c). In (d) to (f), another monomer is not particularly limited as long as it does not hinder characteristics of the polymer of the present invention, and known monomers can be used. Specific examples thereof include monomers such as thiophene derivatives, pyrrole derivatives and furan derivatives, and monomers having a π conjugate structure (e.g., thiadiazole and isothianaphthene).

That is, the polymer according to the present invention can be obtained by polymerizing or copolymerizing one or at least two monomers (hereinafter also referred to as “monomer”) corresponding to the repeating units (1) and (2), and optionally another monomer, in the presence of a metal complex as a polymerization catalyst. Herein, monomers corresponding to the repeating units can be exemplified for the monomers cited above. Examples of preferable monomers corresponding to the repeating unit (1) include the compounds (M1-1) to (M1-22) as above. Examples of preferable monomers corresponding to the repeating unit (2) include the compounds (M2-1) to (M2-10) as above. Note that, needless to add, the present invention is not limited to these monomers. In addition, the monomers are prescribed with the above symbols in Examples below.

In addition, a multimer (oligomer; hereinafter also referred to as “multimer” collectively) such as a dimer or a trimer of a monomer corresponding to the repeating unit (1) represented by the general formula (1) or the repeating unit (2) represented by the general formula (2) may be used in the polymerization or copolymerization. Use of a multimer such as a dimer is preferable since an oxidation potential in polymer formation is small and a polymerization speed of a polymer is shortened as compared to the case of using a monomer. The oligomer of the monomers can be synthesized by, for example, the method described in J. R. Reynolds et. al., Adv. Mater., 11, 1379 (1999) or a method having the method suitably modified. The dimmers of monomers can be synthesized by, for example, the method described in T. M. Swager et. al., Journal of the American Chemical Society, 119, 12568 (1997) or a method having the method suitably modified.

For example, a preferable embodiment of a method for producing the compound (M1-4) and a dimer of the compound (M1-4) will be described below. Note that the present invention is not limited to the following preferable embodiment and other similar methods and other known methods can be applied.

[Synthesis of Compound (M1-4)]

Under a nitrogen atmosphere, 1.44 g (10.0 mmol) of 3,4-dimethoxythiophene, 2.58 g (10.0 mmol) of 1,2-hexadecanediol, and 157 mg (0.83 mmol) of p-toluenesulfonic acid monohydrate were dissolved in 60 mL of toluene, and the mixture was heated at 85 to 90° C. for 21 hours. After reacting for a predetermined time, the reaction product was cooled and then washed with water. An organic layer was dried with MgSO₄, and a filtrate was concentrated. A concentrate was purified by silica gel column chromatography with heptane:ethyl acetate (19:1 (volume ratio)), to yield 1.77 g (5.2 mmol, yield: 52%) of a compound (M1-4) as a yellow white solid. The result of ¹H-NMR analysis of the resultant compound (M1-4) was as described below.

¹H-NMR (CHCl₃): δ (ppm) 0.88 (t, 3H) 1.26 (br, 24H) 1.67 (br, 2H) 3.87 (m, 1H) 4.13 (m, 2H) 6.30 (s, 2H).

[Synthesis of Dimer (DM1-4) of Compound (M1-4)]

Under a nitrogen atmosphere, 1.015 g (3.00 mmol) of the compound (M1-4) thus obtained was dissolved in 12 mL of anhydrous THF, and 0.90 mL (6.0 mmol) of N,N,N′,N′-tetramethylethylenediamine was added thereto. The solution was cooled to −10° C. and then added with 1.8 mL (3.0 mmol) of a solution of n-butyl lithium in hexane (1.67 M). 1.057 g (2.99 mmol) of iron (III) acetyl acetonate was dissolved in 12 mL of anhydrous THF in a container under another nitrogen atmosphere, and added with the above reaction solution and heated to reflux for 6 hours. Then, the reaction mixture was concentrated under reduced pressure, and subjected to purification by silica gel column chromatography with heptane:ethyl acetate (19:1 (volume ratio)), and further purification by molecular sieve chromatography, to yield 328 mg (0.49 mmol, yield: 32%) of a dimer (DM1-4) of the compound (M1-4) as a yellow white solid. The result of ¹H-NMR analysis of the resultant dimer (DM1-4) was as described below.

¹H-NMR (CHCl₃): δ (ppm) 0.88 (t, 6H) 1.26 (br, 48H) 1.68 (br, 4H) 3.93 (m, 2H) 4.18 (m, 4H) 6.23 (s, 2H).

(Polymerization Method of Polymer According to Present Invention)

A polymerization method is not particularly limited and, for example, a known method such as a method described in JP-A-2000-106223 can be applied. Specifically, examples thereof include a chemical polymerization method using a polymerization catalyst, an electrolytic polymerization method in which at least a working electrode and a counter electrode are provided and a voltage is applied between the both electrodes to be reacted, and a photopolymerization method by light irradiation solely or in combination with a polymerization catalyst, heating, electrolysis, and the like. Among these methods, a polymerization method using electrolytic polymerization is preferable. That is, the present invention also provides a method for producing a photoelectric conversion element comprising a substrate, a first electrode, a photoelectric conversion layer containing a semiconductor and a sensitizing dye, a hole transport layer, and a second electrode,

wherein the hole transport layer is formed by electrolytic polymerization using a monomer (1) represented by the following general formula (1′):

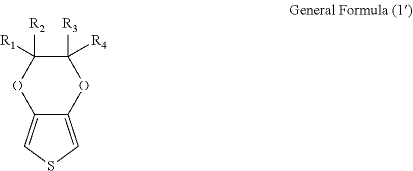

wherein R₁ to R₄ each independently represent a hydrogen atom, a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, provided that at least one of R₁ to R₄ is a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, and the remaining substituents are hydrogen atoms, or a monomer (2) represented by the following general formula (2′):

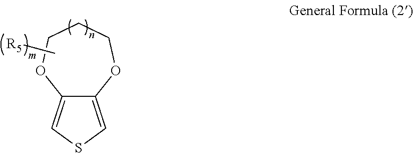

Wherein R₅ each independently represents a halogen atom, a linear or branched alkyl group having 1 to 24 carbon atoms, or an alkoxy group having 1 to 18 carbon atoms, n is an integer from 1 to 3, and m is an integer from 0 to 2n+4, or a multimer thereof. Note that in the general formula (1′), since the definitions of R₁ to R₄ are the same as those defined in the general formula (1), explanation is omitted. Similarly, in the general formula (2′), since the definitions of R₅, n and m are the same as those defined in the general formula (2), explanation is omitted.

When a polymer is obtained by electrolytic polymerization method, synthesis of a polymer directly leads to formation of the hole transport layer. That is, an electrolytic polymerization method as follows is carried out. In general, a mixture containing a monomer that constitutes the polymer according to the present invention, a support electrolyte, a solvent, and optionally an additive is used.

The monomer (1) or (2) corresponding to the repeating unit (1) or (2) of the general formula (1) or the general formula (2), or a multimer of the monomer is dissolved in a suitable solvent, and a support electrolyte is added thereto, to prepare a solution for electrolytic polymerization.

Although the solvent used herein is not particularly limited as long as it can dissolve a support electrolyte, and the monomer or multimer thereof, an organic solvent having a comparatively wide potential window is preferably used. Specific examples thereof include acetonitrile, tetrahydrofuran, propylene carbonate, dichloromethane, o-dichlorobenzene, dimethylformamide, and methylene chloride. Alternatively, a mixed solvent that is prepared by adding optionally water and another organic solvent to the above solvent may be used. In addition, the solvent may be used alone or in a form of a mixture of two or more kinds.

For the support electrolyte, electrolytes capable of ionization can be used, not limited to particular one, and those having high solubility in a solvent, which are not susceptible to oxidation and reduction, are preferably used. Specifically, preferable examples thereof include salts such as lithium perchlorate (LiClO₄), lithium tetrafluoroborate, tetrabutyl ammonium perchlorate, Li[(CF₃SO₂)₂N], (n-C₄H₉)₄NBF₄, (n-C₄H₉)₄NPF₄, p-toluenesulfonic acid salt, and dodecyl benzenesulfonic acid salt. Alternatively, polymer electrolytes described in JP-A-2000-106223 (for example, PA-1 to PA-10 cited in the publication) may be used as the support electrolyte. The support electrolyte may be used alone or in a form of a mixture of two or more kinds.

Then, the substrate 1 on which the first electrode (transparent conductive film) 2, the barrier layer 3 and the photoelectric conversion layer 6 are formed is immersed in the solution for electrolytic polymerization, and directly subjected to electrolysis using the photoelectric conversion layer 6 as a working electrode, a platinum wire or a platinum plate as a counter electrode, and Ag/AgCl, Ag/AgNO₃ or the like as a reference electrode. A concentration of the monomer or multimer thereof in the solution for electrolytic polymerization is not particularly limited, and is preferably approximately 0.1 to 1.000 mmol/L, more preferably approximately 1 to 100 mmol/L, and particularly preferably approximately 5 to 20 mmol/L. A concentration of the support electrolyte is preferably approximately 0.01 to 10 mol/L, and more preferably approximately 0.1 to 2 mol/L. An electric current density to be applied is desirably within the range from 0.01 μA/cm² to 1,000 μA/cm², and particularly desirably within the range from 1 μA/cm² to 500 μA/cm². A retention voltage is preferably −0.50 to +0.20 V, and more preferably −0.30 to 0.00 V. A temperature range of the solution for electrolytic polymerization is suitably such a range as that the solvent does not solidify or explosively boil, and generally from −30° C. to 80° C. Conditions such as electrolysis voltage, electrolysis current, electrolysis time, temperature, and the like may depend on materials to be used, and thus, the conditions can be suitably selected in consideration of a desired film thickness.

A polymerization degree of a polymer obtained by electrolytic polymerization is understood with difficulties. For a method of confirming a polymer or not, the polymerization degree can be determined with the solubility when the hole transport layer is immersed in tetrahydrofuran (THF) that is a solvent capable of dissolving a monomer corresponding to the repeating unit (1) or (2) of the general formula (1) or the general formula (2), since the solvent solubility of the hole transport layer formed after polymerization is largely reduced.

Specifically, 10 mg of a compound (polymer) is charged in a 25 ml-sample bottle, 10 ml of THF is added thereto, and when the ultrasonic wave (25 kHz, 150 W, ULTRASONIC ENGINEERING CO., LTD., COLLECTOR CURRENT 1.5 A, manufactured by ULTRASONIC ENGINEERING CO., LTD., 150) is irradiated for 5 minutes, a case of 5 mg or less of the dissolved compound is determined as being polymerized.

On the other hand, when chemical polymerization is carried out using a polymerization catalyst, a monomer corresponding to the repeating unit (1) or (2) of the general formula (1) or the general formula (2) or multimer thereof can be polymerized using a polymerization catalyst as below. Note that the present invention is not limited to the followings. That is, the polymerization catalyst is not particularly limited, and examples thereof include iron (III) chloride, iron (III) tris-p-toluenesulfonate, iron (III) p-dodecylbenzenesulfonate, iron (III) methanesulfonate, iron (III) p-ethylbenzenesulfonate, iron (III) naphthalenesulfonate, and hydrates thereof.

A polymerization modifier may be used in chemical polymerization in addition to a polymerization catalyst. The polymerization modifier which can be used in chemical polymerization is not particularly limited as long as it has a weak complexing to trivalent iron ion in the polymerization catalyst and reduces a polymerization speed so that a film can be formed. For example, when a polymerization catalyst is iron (III) chloride or a hydrate thereof, examples thereof include aromatic oxysulfonic acids such as 5-sulphosalicylic acid. When a polymerization catalyst is iron (III) tris-p-toluenesulfonate, iron (III) p-dodecylbenzenesulfonate, iron (III) methanesulfonate, iron (III) p-ethylbenzenesulfonate, iron (III) naphthalenesulfonate, or a hydrate thereof, examples thereof include imidazole, and the like.

The polymer may be incorporated in a coating liquid, or the like containing the polymer to provide on a photoelectric conversion layer after being synthesized, but it is preferable that polymerization is carried out on the photoelectric conversion layer to form a hole transport layer. That is, electrolytic polymerization of the monomer (1), monomer (2) or multimer thereof is preferably carried out on the photoelectric conversion layer.

In this case, a solution for forming hole transport layer that contains the monomer corresponding to the repeating unit (1) or (2) of the general formula (1) or general formula (2) or multimer thereof, the polymerization catalyst, the polymerization modifier, and another additive is used in the polymerization to synthesize a polymer. A total concentration of these components in the solution for forming hole transport layer may be varied depending on a kind, an amount of each of the monomer corresponding to the repeating unit (1) or (2) of the general formula (1) or general formula (2) or multimer thereof, the polymerization catalyst, the polymerization modifier, and another additive, conditions for a coating method, and a desired film thickness after polymerization, and the concentration is approximately within the range from 1 to 50% by weight.

A polymerization reaction is carried out after coating the solution for forming hole transport layer on a photoelectric conversion layer by a coating method, or with a photoelectric conversion layer immersed in the solution for forming hole transport layer.

The conditions of the polymerization reaction may be varied depending on a kind, an amount, a concentration of each of the monomer corresponding to the repeating unit (1) or (2) of the general formula (1) or general formula (2) or multimer thereof, the polymerization catalyst, and the polymerization modifier, a thickness of a liquid film in the stage of coating, and a desired polymerization speed. For preferable polymerization conditions, a heating temperature in the case of heating in the air is within the range from 25 to 120° C., and a heating time is preferably within the range from 1 minute to 24 hours.

The polymer according to the present invention has the repeating unit (1) or (2) of the general formula (1) or general formula (2), and a repeating unit other than the repeating units may be contained in combination in such an amount as not to damage effects by the present invention. Examples of the other repeating unit include repeating units derived from a monomer such as a thiophene derivative, a pyrrole derivative or a furan derivative. In addition, a divalent organic group having a π conjugate structure as represented by the following general formula (4) is also preferable for a repeating unit in combination use.

*Ar* General formula (4)

In the general formula (4), Ar represents a divalent organic group having a π conjugate structure. As used herein, “π conjugate structure” is referred to as a structure in which multiple bonds and single bonds are alternately continued. When the organic group having such a π conjugate structure is present in a polymer, the π conjugate plane surface of the polymer extends, electron donation property of the repeating unit (1) or (2) of the general formula (1) or general formula (2) is increased, and characteristics of a p-type semiconductor are thus more improved. Specific examples of such a monomer corresponding to a repeating unit of the general formula (4) include thiadiazole and isothianaphthene.

When a hole transport layer is formed by coating, the solution for forming hole transport layer is used. Examples of a solvent for the coating liquid include organic solvents such as polar solvents including tetrahydrofuran (THF), butylene oxide, chloroform, cyclohexanone, chlorobenzene, acetone, and various alcohols, and non-protonic solvents including dimethylformamide (DMF), acetonitrile, dimethoxyethane, dimethyl sulfoxide, and hexamethylphosphoric triamide. The solvents may be used alone or in a form of a mixture of two or more kinds.

To the hole transport layer, for example, various additives including acceptor doping agents such as N(PhBr)₃SbCl₆, NOPF₆, SbCl₅, I₂, Br₂, HClO₄, (n-C₄H₉)₄ClO₄, trifluoroacetic acid, 4-dodecylbenzenesulfonate, 1-naphthalenesulfonate, FeCl₃, AuCl₃, NOSbF₆, AsF₅, NOBF₄, LiBF₄, H₃[PMo₁₂O₄₀], and 7,7,8,8-tetracyanoquinodimethane (TCNQ), binder resins that hardly trap a hole, coating improving agents such as a leveling agent may be optionally added. The additives may be used alone or in a form of a mixture of two or more kinds.

A coating method is not particularly limited, and a known method can be used in the same manner or with suitable modification. Specifically, various coating methods such as dipping, dropping, doctor blade, spin coating, brush coating, spray coating, roll coater, air knife coating, curtain coating, wire-bar coating, gravure coating, extrusion coating using a hopper as described in U.S. Pat. No. 2,681,294, and multilayer simultaneous coating as described in U.S. Pat. Nos. 2,761,418, 3,508,947, and 2,761,791, can be used. Such coating may be repeatedly carried out to form a laminated layer. In this case, the number of coating is not particularly limited, and can be suitably selected according to a desired thickness of a hole transport layer.

The content of the polymer having the repeating unit (1) or (2) in the hole transport layer is not particularly limited. In considering hole transport characteristics, suppression and prevention ability of disappearance of an exciter generated around the interface of the photoelectric conversion layer, and the like, the content of the polymer is preferably 50 to 100% by weight, and more preferably 90 to 100% by weight, based on the whole amount of monomer(s).

In the present invention, the hole transport layer is preferably hole-doped in order to enhance conductivity thereof. The hole-doping amount is not particularly limited, and is preferably 0.15 to 0.66 (holes) per the repeating unit (1) or (2) of the general formula (1) or general formula (2).

In electrolytic polymerization, the polymer having the repeating unit represented by the general formula (1) or general formula (2) is oxidized by applying an electric field to be hole-doped.

A photopolymerization method of polymerizing by light irradiation may be used in combination in electrolytic polymerization. According to such a method, a polymer layer can be finely formed on a titanium oxide surface.

In order to reduce an oxidant of a sensitizing dye in the photoelectric conversion layer, the polymer according to the present invention preferably has an ionized potential smaller than that of a dye adsorption electrode. A range of the ionized potential of the polymer according to the present invention is not particularly limited, and may be varied depending on a sensitizing dye to be used. In a state that the polymer is doped, the ionized potential of the polymer is preferably from 4.5 eV to 5.5 eV, and more preferably from 4.7 eV to 5.3 eV.

The reason for obtaining a photoelectric conversion element excellent in photoelectric conversion efficiency and stability of photoelectric conversion function by using the hole transport layer according to the present invention is not clear but can be presumed as follow. Note that the present invention is not limited by the presumption below. That is, absorption in visible and infrared range (wavelength of 400 nm or more) in a conductive polymer is generally caused by the following three factors: [1] π-π* transition of a neutral conjugate polymer (400 to 700 nm); [2] absorption by polaron (500 to 1500 nm); and [3] absorption by bipolaron (1,000 nm or more). In order to be transparent in the visible range (wavelength of 400 to 700 nm), a polymer can be designed so as to suppress absorption of [1] and [2] and attaining only [3]. When a hole doping amount per a unit is 0.15 to 0.66 (hole), a neutral conjugate portion and an existence ratio of polaron in the polymer according to the present invention is decreased, and a main component constituting a polymer chain is bipolaron. Visible light permeability is more improved since formation of bipolaron is promoted and a neutral conjugate portion and polaron further decrease when the polymer has the repeating unit (1) or (2). As a result, since loss of the visible light due to absorption of the polymer decreases, the visible light acting on a sensitizing dye increases, which results in improvement in photoelectric conversion efficiency.

It is also presumed that the polymer according to the present invention itself has a low visible light absorption and suppressed degradation due to light, which results in stabilization of photoelectric conversion function. In addition, when the polymer according to the present invention has an alkyl group with a long chain (for example, 6 to 18 carbon atoms), it is presumed that the alkyl group acts as a functional group that promotes self-cohesion to improve durability due to formation of self-cohesion structure.

Therefore, a preferable hole transport layer has absorbance of 1.0 or less, since loss of light in absorption is decreased and degradation due to light can be suppressed when a visible light absorption is low. Further, when the polymerization degree of the polymer increases, absorbance slightly increases, and in order to attain a polymerization degree having preferable hole transport ability, a charge transport layer having a polymerization degree showing absorbance of 0.2 or more is preferable. Therefore, the polymer according to the present invention has an absorbance in 400 to 700 nm (an average absorbance measured with an interval of 50 nm within the wavelength region from 400 to 700 nm) of preferably 0.2 to 1.0.

In the present description, absorbance of the hole transport layer (polymer) is defined using an absorbance gap of a working electrode before and after electrolytic polymerization, and the absorbance is referred to as an average absorbance measured within the wavelength region from 400 to 700 nm. The absorbance is measured using a spectrophotometer (JASCO V-530). For the working electrode, one obtained by adsorbing a dye to a titanium oxide thin film with an effective area of 10×20 mm², which is formed on a FTO conductive glass substrate, is used, and immersed in a solution with the same composition as that of the solution for electrolytic polymerization as mentioned above. A polymer having a repeating unit of the general formula (1) or general formula (2) is formed on the working electrode by using a platinum wire as a counter electrode, Ag/Ag⁺(AgNO₃ 0.01M) as a reference electrode, and setting a retention voltage at −0.16 V, and maintaining the voltage for 30 minutes while irradiating light from the direction of the semiconductor layer (using xenon lamp, light intensity of 22 mW/cm², cutting a wavelength of 430 nm or less), which is used for measurement of absorbance. In order to correct influence of variation of film thicknesses, a film thickness of a sample is measured, and a value obtained by dividing the absorbance with the film thickness (μm) is used. A film thickness is measured with Dektak 3030 (manufactured by SLOAN TECHNOLOGY Co.).

(Sensitizing Dye)

The sensitizing dye according to the present invention is supported on a semiconductor by a sensitizing treatment of the semiconductor as described above, photoexcited at the time of light irradiation to be able to generate electromotive force, and is a compound represented by the following general formula (3A), (3B) or (3C):

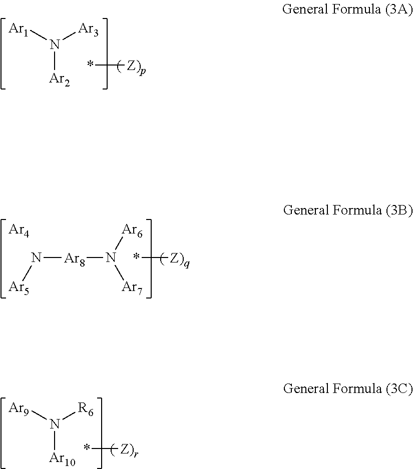

In the general formula (3A), Ar₁ to Ar₃ represent an aromatic group. In this condition, any two of Ar₁ to Ar₃ may bond each other to form a ring structure. Ar₁ to Ar₃ may be the same or different each other. p is an integer from 1 to 3, and preferably 1 or 2. In the general formula (3B), Ar₄ to Ar₇ represent an aromatic group. In this condition, Ar₄ and Ar₅ or Ar₆ and Ar₇ may bond each other to form a ring structure. Ar₄ to Ar₇ may be the same or different each other. Ar₈ is a divalent aromatic group. q is an integer from 1 to 4, and preferably 1 or 2. In the general formula (3C), Ar₉ and Ar₁₀ represent an aromatic group. Ar₉ and Ar₁₀ may be the same or different each other. R₆ represents a linear or branched alkyl group having 1 to 24 carbon atoms, or a cycloalkyl group having 3 to 9 carbon atoms. In this condition, Ar₉ and Ar₁₀, or Ar₉ or Ar₁₀ and R₆ may bond each other to form a ring structure. r is an integer of 1 or 2, and preferably 1. In the general formulas (3A) to (3C), Z represents a group having an acidic group and an electron-attracting group or a group having an acidic group and an electron-attracting ring structure, which is substituted in any of Ar₁ to Ar₁₀.

As used herein, monovalent or divalent aromatic group represented by Ar₁ to Ar₁₀ are not particularly limited. Specifically, the monovalent or divalent aromatic group may be derived from aromatic rings such as benzene ring, naphthalene ring, anthracene ring, thiophene ring, phenylthiophene ring, diphenylthiophene ring, imidazole ring, oxazole ring, thiazole ring, pyrrole ring, furan ring, benzimidazole ring, benzoxazole ring, rhodanine ring, pyrazolone ring, imidazolone ring, pyran ring, pyridine ring, and fluorene ring. A plurality of these aromatic rings may be used in combination, and examples thereof include biphenyl group, terphenyl group, fluorenyl group, bithiophene group, 4-thienylphenyl group, and diphenylstyryl group, as well as stilbene, 4-phenylmethylene-2,5-cyclohexadiene, triphenylethene (e.g., 1,1,2-triphenylethene), phenylpyridine (e.g, 4-phenylpyridine), styrylthiophene (e.g., 2-styrylthiophene), 2-(9H-fluorene-2-yl)thiophene, 2-phenylbenzo[b]thiophene, phenylbithiophene ring, (1,1-diphenyl-4-phenyl)-1,3-butadiene, 1,4-diphenyl-1,3-dibutadiene, 4-(phenyl methylene)-2,5-cyclohexadiene, and phenyl dithienothiophene ring. These aromatic rings may have an substituent, and examples of the substituent include halogen atoms (e.g., fluorine, chlorine, and bromine), each substituted or non-substituted, linear or branched alkyl group having 1 to 24 carbon atoms (e.g., methyl group, ethyl group, t-butyl group, isobutyl group, dodecyl group, octadecyl group, and 3-ethylpentyl group), hydroxyalkyl group (e.g., hydroxymethyl group and hydroxyethyl group), alkoxyalkyl group (e.g., methoxyethyl group), alkoxy group having 1 to 18 carbon atoms (e.g., methoxy group, ethoxy group, propoxy group, isopropoxy group, butoxy group, pentyloxy group, and hexyloxy group), aryl group (e.g., phenyl group and tolyl group), alkenyl group (e.g., vinyl group and allyl group), amino group (e.g., dimethylamino group, diethylamino group and diphenylamino group), and heterocyclic group (e.g., morpholyl group and furanyl group).

Among the general formulas (3A) to (3C), a sensitizing dye represented by the general formula (3A) is preferable, and is particularly preferably combined with a hole transport layer comprising a polymer having a repeating unit (1) represented by the general formula (1). Among sensitizing dyes represented by the general formula (3A), a sensitizing dye represented by the general formula (3D) is preferable, and a sensitizing dye represented by the general formula (3D) wherein Ar₁₁ and Ar₁₂ contain a thiophene ring is particularly preferable.

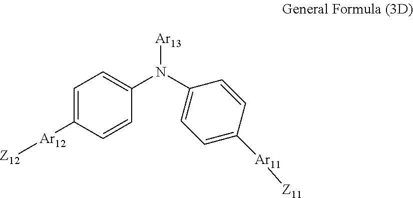

In the general formula (3C), R₆ represents a linear or branched alkyl group having 1 to 24 carbon atoms or a cycloalkyl group having 3 to 9 carbon atoms. The linear or branched alkyl group having 1 to 24 carbon atoms and the cycloalkyl group having 3 to 9 carbon atoms are the same definitions of R₁ to R₄ in the general formula (1). Among these, a linear or branched alkyl group having 1 to 18 carbon atoms and a cycloalkyl group having 3 to 7 carbon atoms are preferable, a linear alkyl group having 1 to 6 carbon atoms such as methyl group, ethyl group, n-propyl group, n-butyl group, n-pentyl group, and an n-hexyl group, a branched alkyl group having 3 to 6 carbon atoms such as isopropyl group and t-butyl group, and a cycloalkyl group having 5 to 6 carbon atoms such as cyclopentyl group and cyclohexyl group are more preferable.

In the general formulas (3A) to (3C), Z represents a group having an acidic group and an electron-attracting group or a group having an acidic group and an electron-attracting ring structure, which is substituted in any of Ar₁ to Ar₁₀. The substituting group Z is substituted with any of hydrogen atoms (H) present in Ar₁ to Arₐ in the general formula (3A), Ar₄ to Ar₇ in the general formula (3B), and Ar₉, Ar₁₀ and R₆ (preferably, Ar₉ and Ar₁₀) in the general formula (3C), and preferably substituted to a hydrogen atom (H) in the terminal of the above Ar. Examples of the acidic group in the substituting group Z include carboxyl group, sulfo group [—SO₃H], sulfino group, sulfinyl group, phosphonic acid group [—PO(OH)₂], phosphoryl group, phosphinyl group, phosphono group, thiol group, hydroxy group, phosphonyl and sulfonyl group; and salts thereof. Among these, for the acidic group, carboxyl group, sulfo group, phosphonic acid group, and hydroxy group are preferable, and carboxyl group, sulfo group, and phosphonic acid group are more preferable. Examples of the electron-attracting group include cyano group, nitro group, fluoro group, chloro group, bromo group, iode group, perfluoroalkyl group (for example, trifluoromethyl group), alkylsulfonyl group, arylsulfonyl group, perfluoroalkylsulfonyl group, and perfluoroaryl sulfonyl group. Among these, cyano group, nitro group, fluoro group, and chloro group are preferable, and cyano group and nitro group are more preferable. Examples of the electron-attracting ring structure include rhodanine ring, dirhodanine ring, imidazolone ring, pyrazolone ring, pyrazoline ring, quinone ring, pyran ring, pyrazine ring, pyrimidine ring, imidazole ring, indole ring, benzothiazole ring, benzoimidazole ring, benzooxazole ring, and thiadiazole ring. Among these, rhodanine ring, dirhodanine ring, imidazolone ring, pyrazoline ring, quinone ring, and thiadiazole ring are preferable, and rhodanine ring, dirhodanine ring, imidazolone ring, and pyrazoline ring are more preferable. The substituting group Z can effectively inject photoelectrons into a semiconductor (particularly, an oxide semiconductor). In the substituting group Z, an acidic group may be connected with an electron-attracting group or an electron-attracting ring structure through an atom such as an oxygen atom (O), a sulfur atom (S), a selenium atom (Se), or a tellurium atom (Te). Alternatively, the substituting group Z may be charged, particularly positively charged, and in this time, the substituting group Z may have a counter ion such as Cl⁻, Br⁻, I⁻, ClO₄⁻, NO₃⁻, SO₄²⁻, and H₂PO₄⁻.

That is, preferable examples of the substituting group Z in the general formulas (3A) to (3C) include the following:

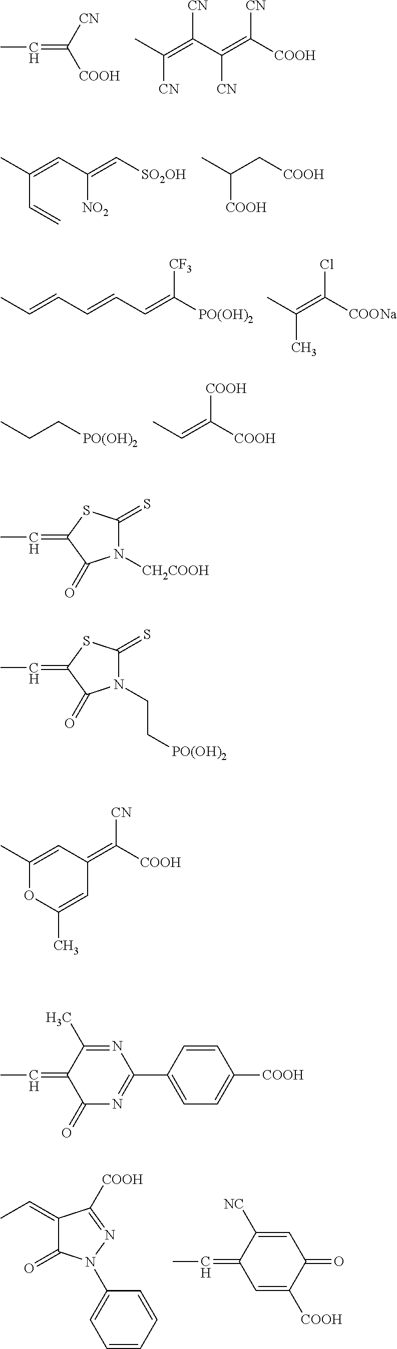

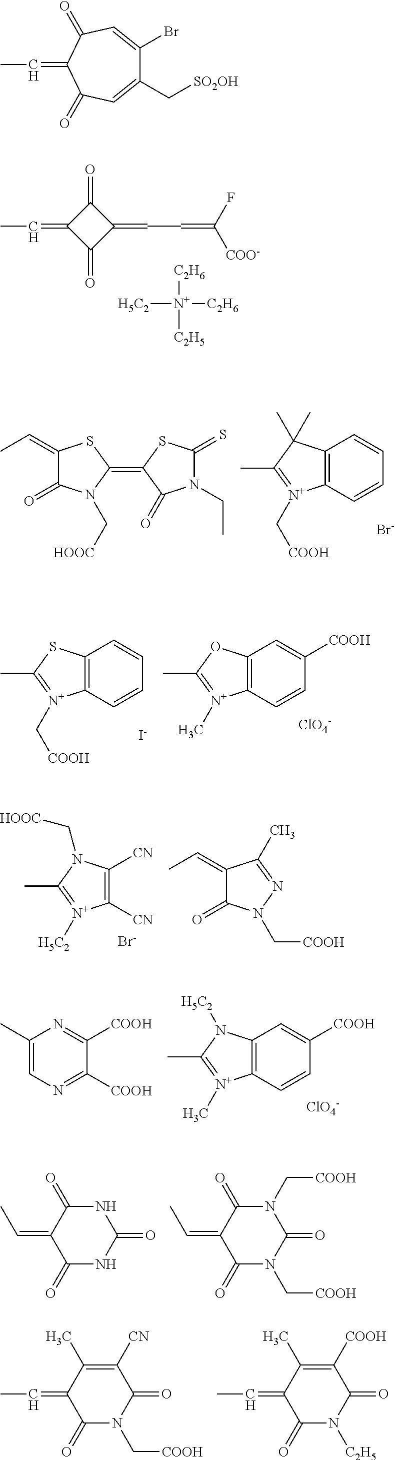

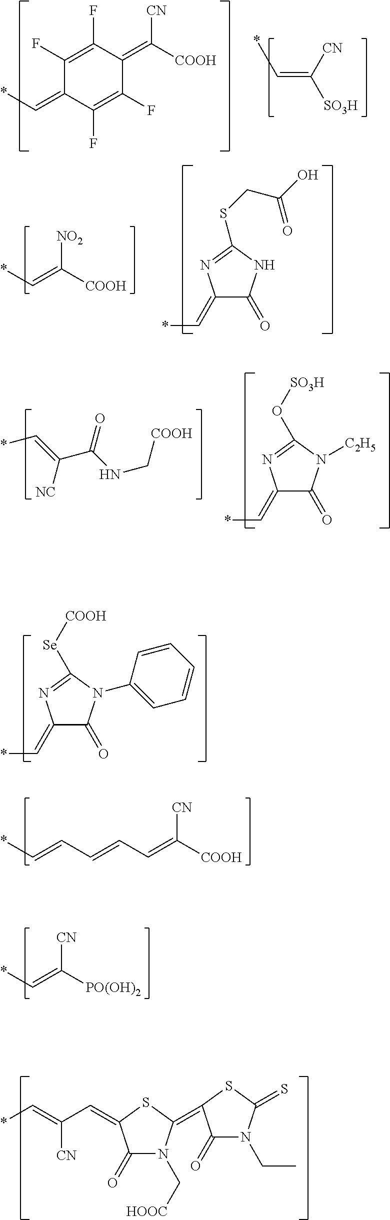

Particularly preferable examples of the sensitizing dye according to the present invention will be shown below. Note that the present invention is not limited thereto. in the following examples, “Ph” denotes a phenyl group. In addition, the sensitizing dye is prescribed as the following symbols in examples described below.

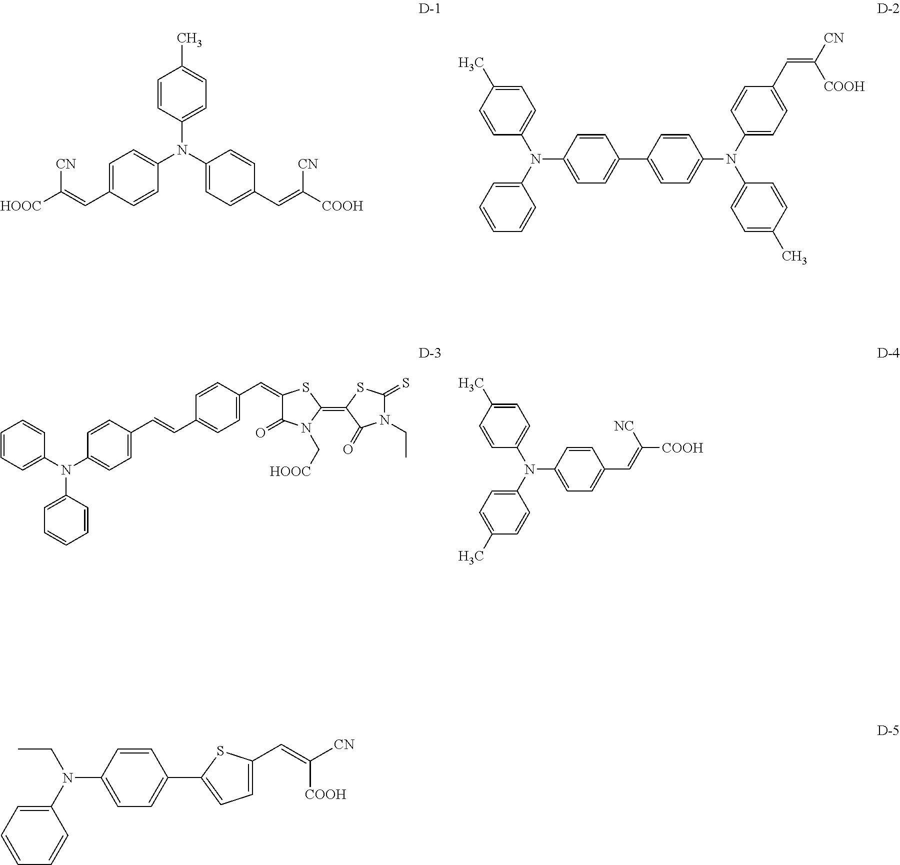

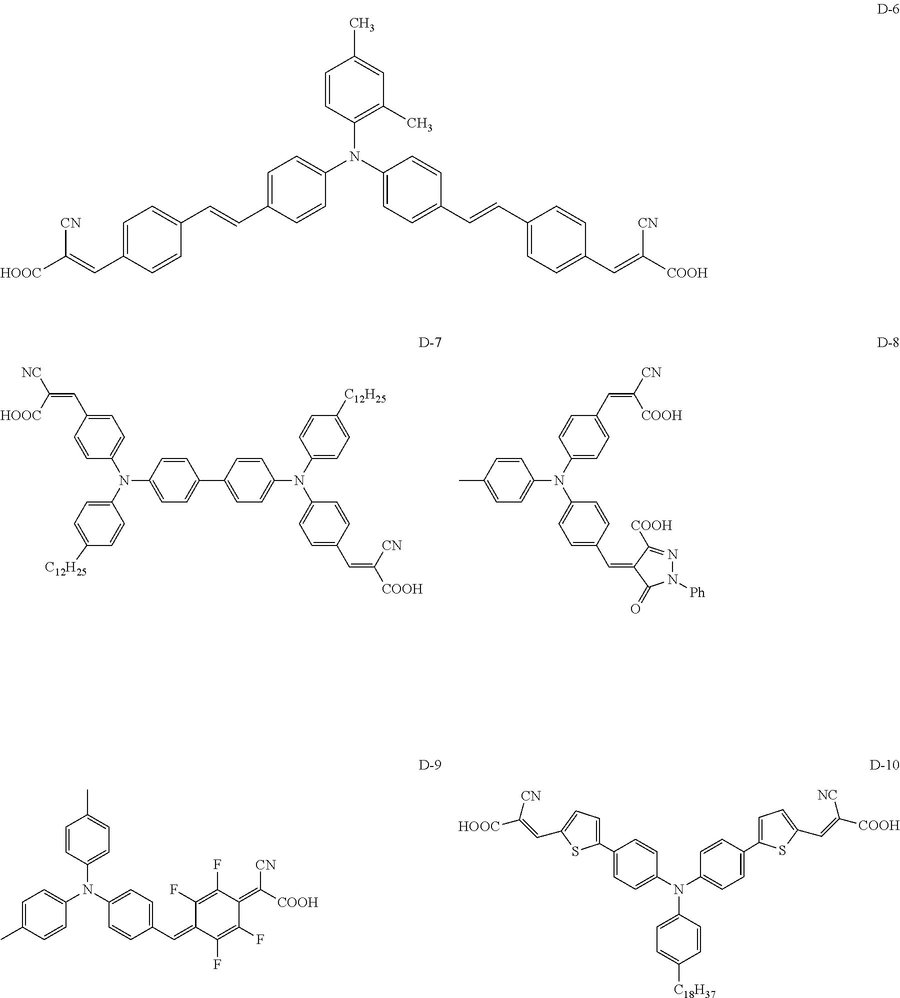

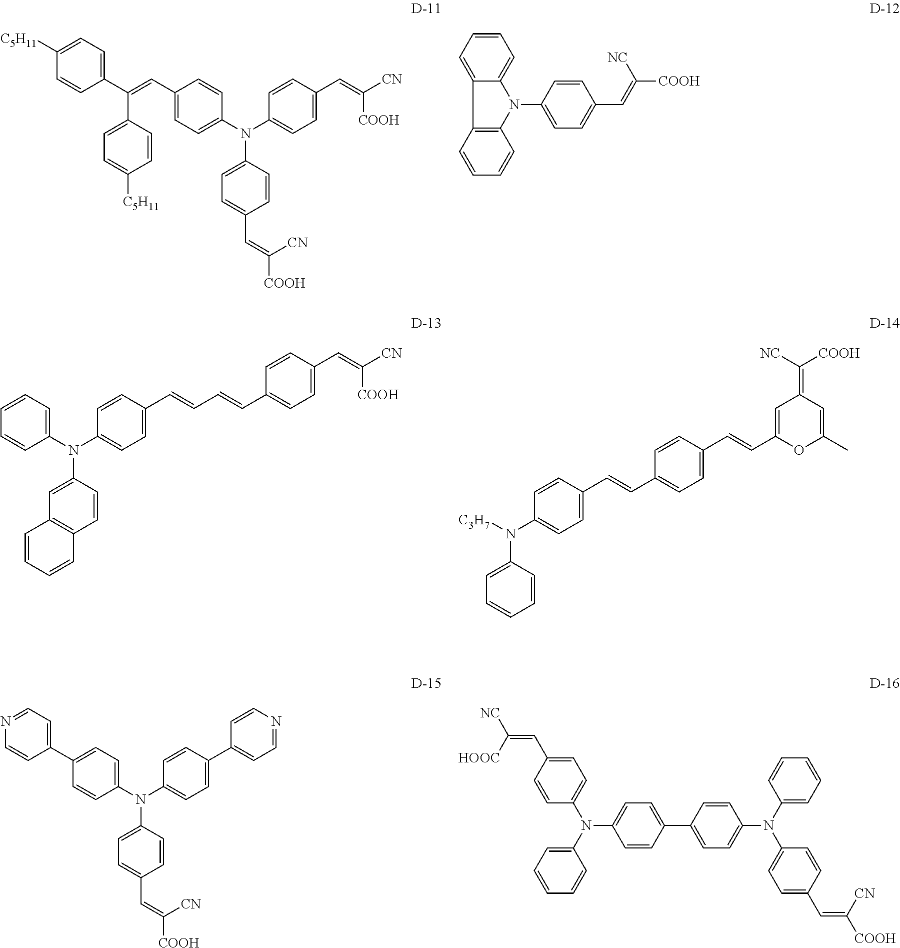

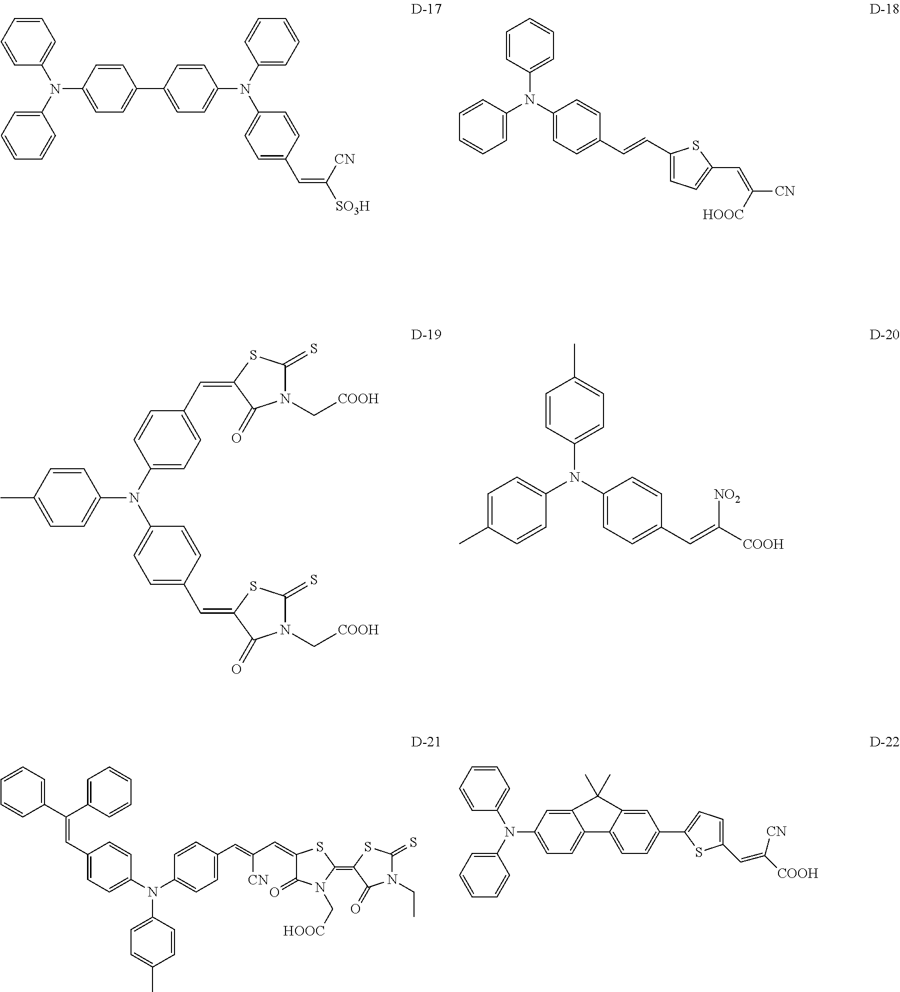

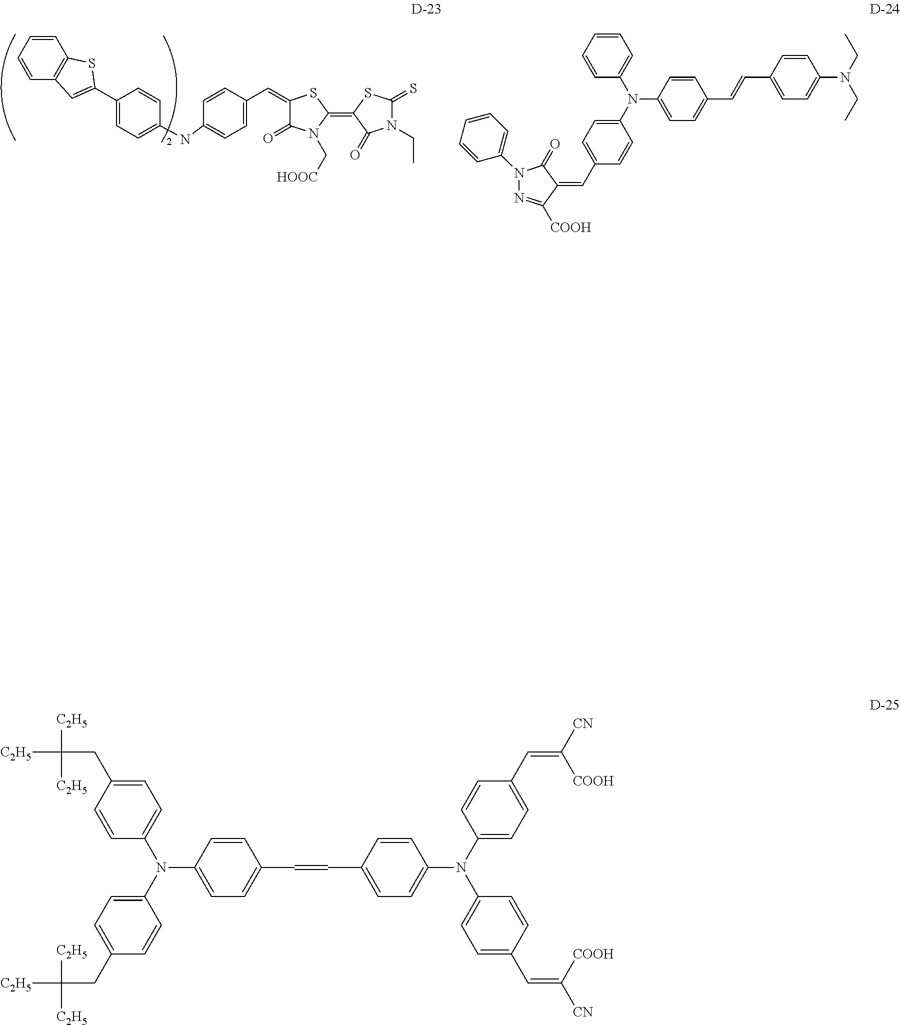

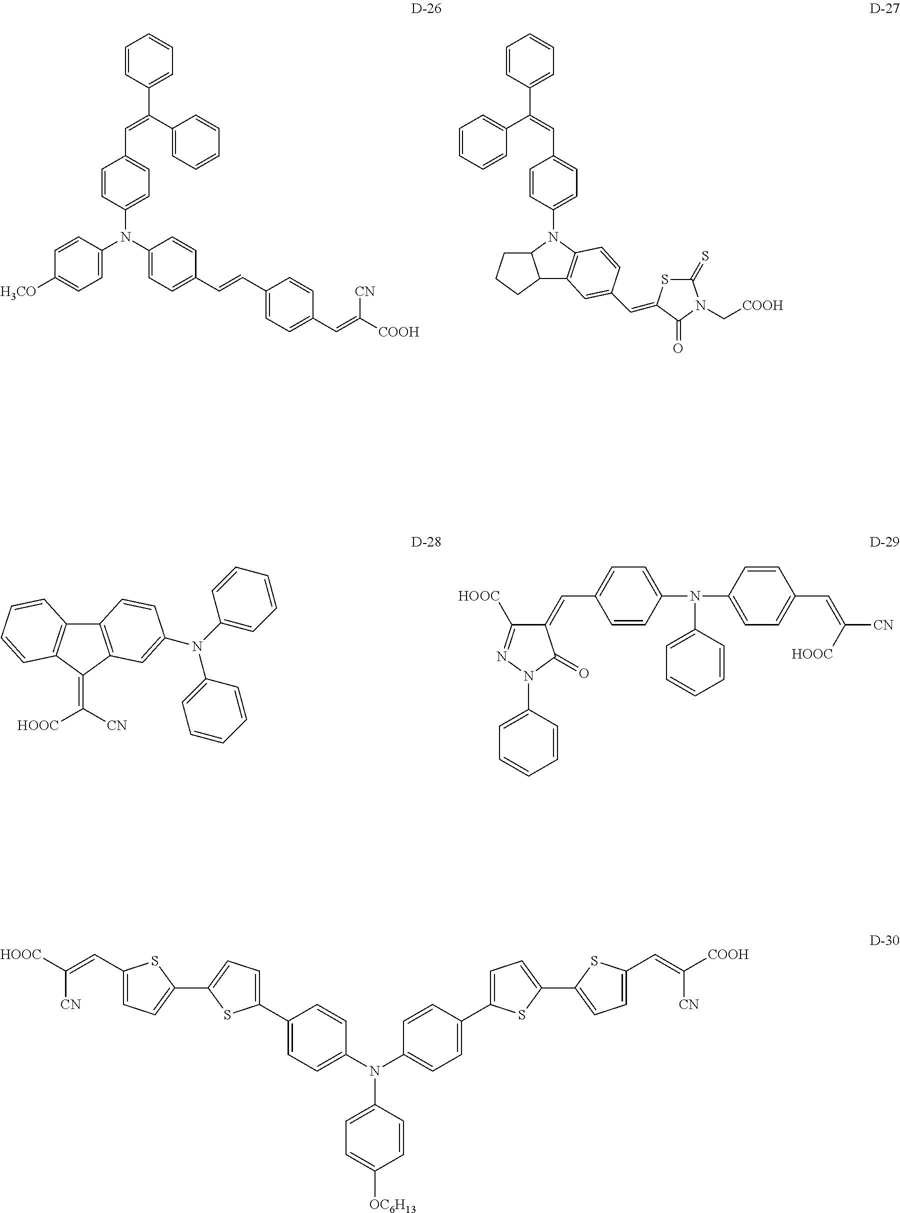

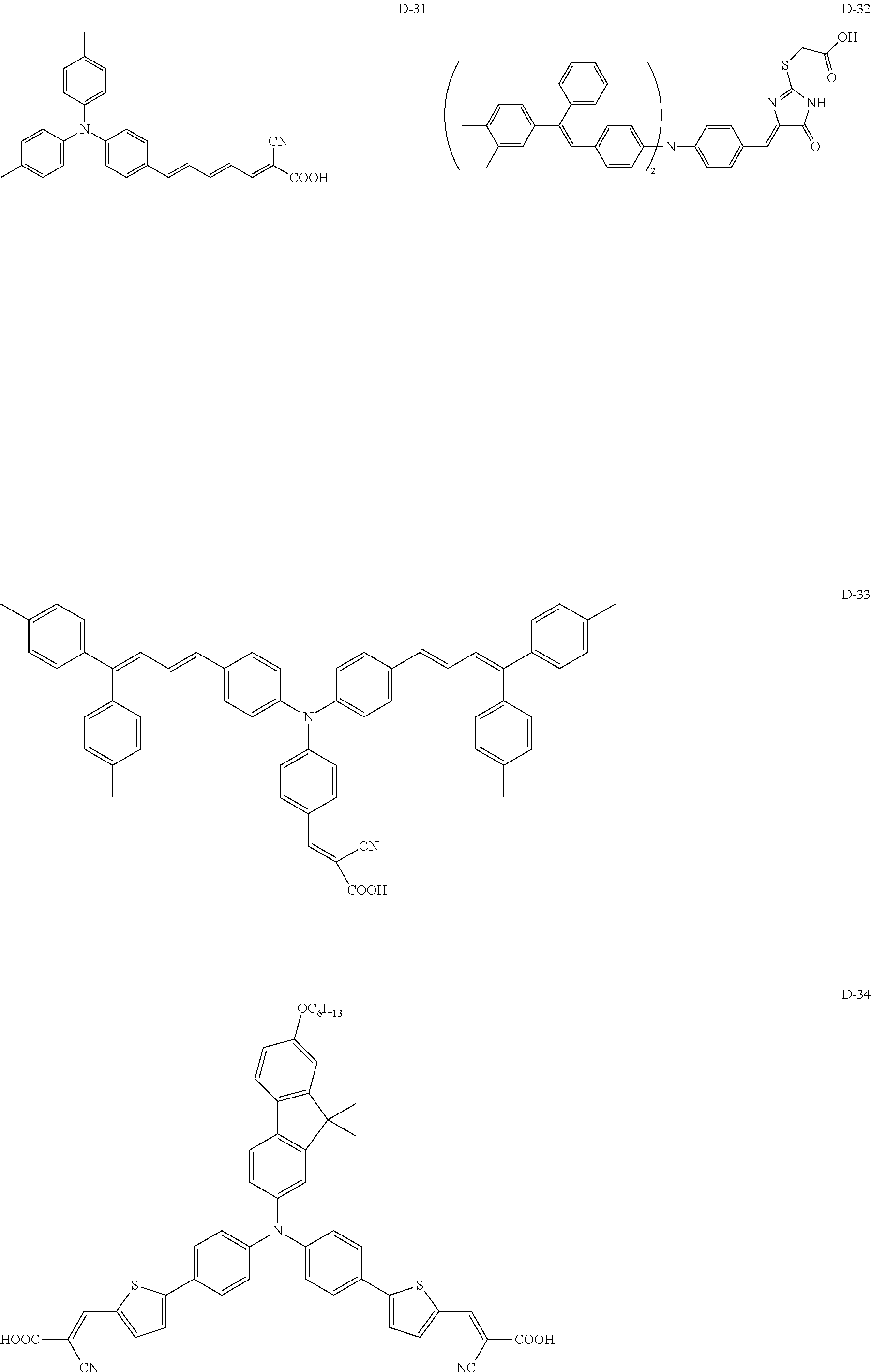

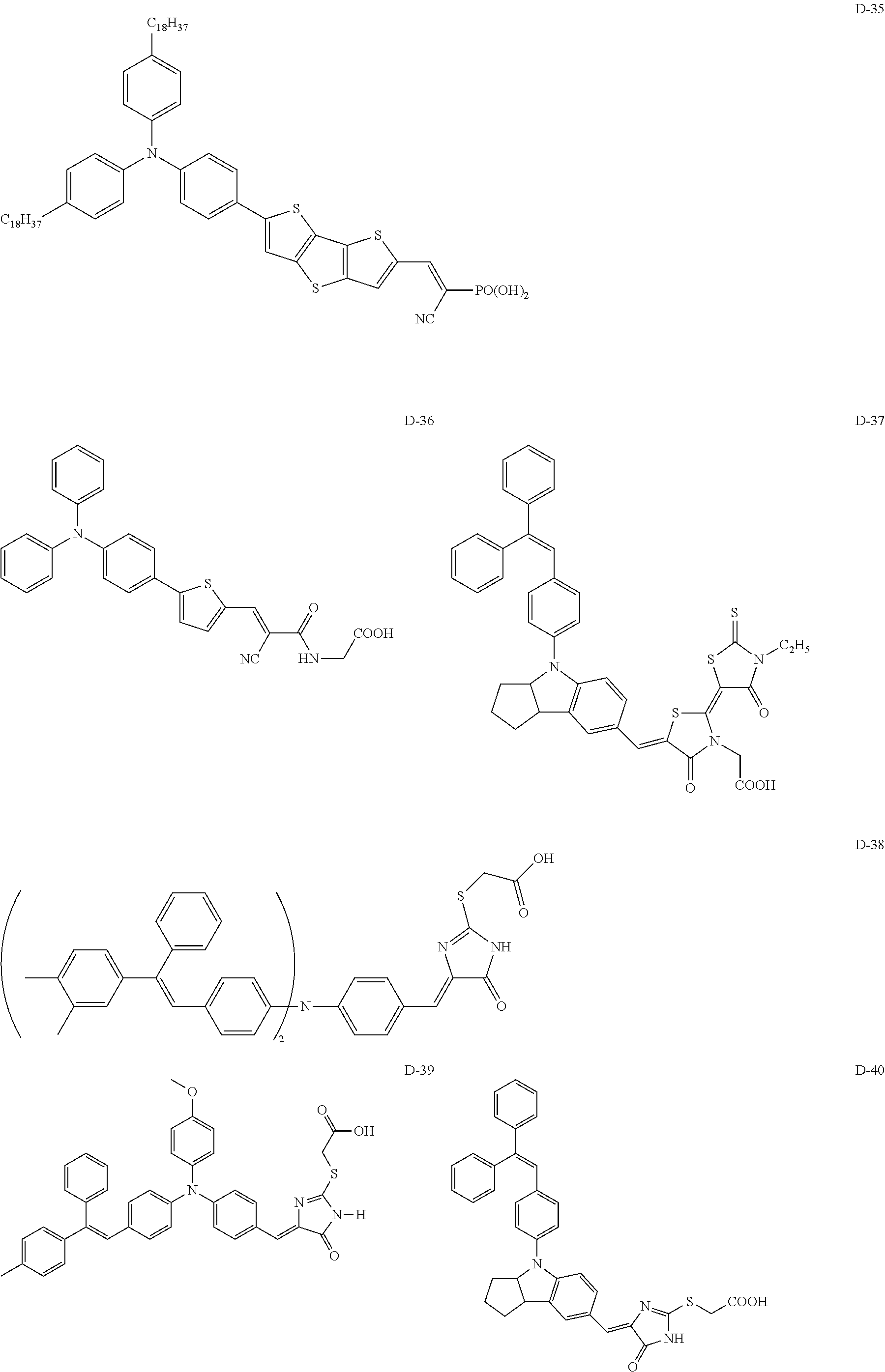

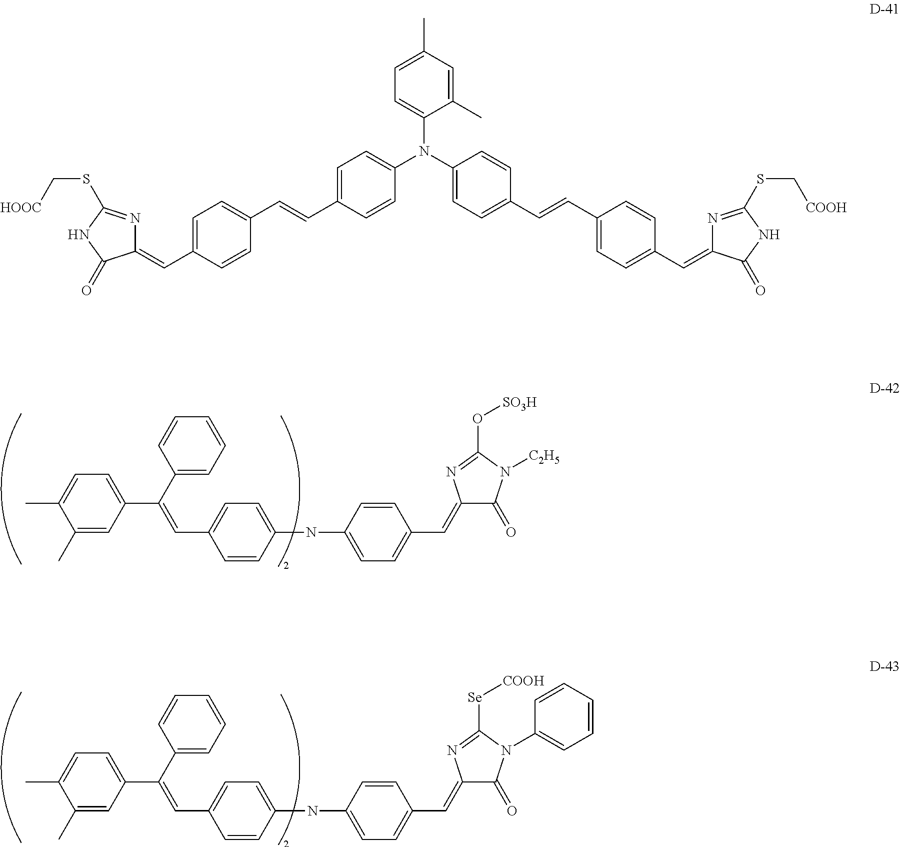

(Substrate)

A substrate is provided in the side of the light incident direction, and from the viewpoint of photoelectric conversion efficiency of a photoelectric conversion element, the substrate has light transmittance of preferably 10% or more, more preferably 50% or more, and particularly preferably 80% to 100%.

The light transmittance as used herein refers to as a total luminous transmittance invisible light wavelength region measured in a method in accordance with “Plastics—Determination of the total luminous transmittance of transparent materials” of JIS K 7361-1:1997 (corresponding to ISO 13468-1:1996).

For the substrate, its materials, shape, structure, thickness, hardness, and the like can be suitably selected among known ones, and a substrate having high light permeability as described above is preferable.

Substrates are roughly divided into substrates having rigidity such as a glass plate and acrylic plate and substrates having flexibility such as a film substrate. Among the former substrates having rigidity, a glass plate is preferable from the viewpoint of heat resistance, and a kind of glass is not particularly limited. A thickness of a substrate is preferably 0.1 to 100 mm, and more preferably 0.5 to 10 mm.

Examples of the latter substrates having flexibility include polyester resin films such as of polyethylene terephthalate (PET), polyethylene naphthalate, and modified polyester, polyolefin resin films such as polyethylene (PE) resin films, polypropylene (PP) resin films, polystyrene resin films, and cyclic olefin resin films, vinyl resin films such as of poly(vinyl chloride) and poly(vinylidene chloride), polyvinylacetal resin films such as of polyvinyl butyral (PVB), polyether ether ketone (PEEK) resin films, polysulfone (PSF) resin films, polyether sulfone (PES) resin films, polycarbonate (PC) resin films, polyamide resin films, polyimide resin films, acrylic resin films, and triacetyl cellulose (TAC) resin films. An inorganic glass film may be used as a substrate in combination with the resin film. A thickness of a substrate is preferably 1 to 1,000 μm, and more preferably 10 to 100 μm.

When a resin film has a transmittance of 80% or more in wavelength in visible light region (400 to 700 nm), the resin film can be particularly preferably applied to the present invention.

From the viewpoint of transparency, heat resistance, easy handling, strength and cost, in particular, a substrate is preferably a biaxially-oriented polyethylene terephthalate film, a biaxially-oriented polyethylene naphthalate film, a polyether sulfone film, or a polycarbonate film, and more preferably a biaxially-oriented polyethylene terephthalate film or a biaxially-oriented polyethylene naphthalate film.

The substrate can be subjected to surface treatment or provided with a readily adhesive layer, in order to secure wetting property and adhesion property of a coating liquid.

Conventionally known techniques can be used for the surface treatment and the readily adhesive layer. Examples of the surface treatment include surface-activating treatments such as corona discharge treatment, flame treatment, ultraviolet treatment, high-frequency treatment, glow discharge treatment, active plasma treatment, and laser treatment.

Examples of the readily adhesive layer include those of polyester, polyamide, polyurethane, vinyl copolymer, butadiene copolymer, acrylic copolymer, vinylidene copolymer, and epoxy copolymer.

(First Electrode)

The first electrode is arranged between the substrate and the photoelectric conversion layer. The first electrode is provided on the surface opposite to the light incident direction of the substrate. For the first electrode, one preferably having a light transmittance of 80% or more, and one more preferably having a light transmittance of 90% or more (upper limit: 100%) is used. The light transmittance is as defined in the explanation of the substrate mentioned above.

Materials forming the first electrode are not particularly limited, and known materials can be used. Examples thereof include metals such as platinum, gold, silver, copper, aluminum, rhodium, and indium; and metal oxides thereof such as SnO₂, CdO, ZnO, CTO-based (CdSnO₃, Cd₂SnO₄, CdSnO₄), In₂O₃, and CdIn₂O₄. Among these, silver is preferably used. A film having an opening which is subjected to grid patterning or a film to which fine particles or nanowires are dispersed to be applied is preferably used in order to impart light permeability. Preferable examples of the metal oxide include complex (doped) materials obtained by adding one or at least two selected from Sn, Sb, F and Al to the above metal oxides. Conductive metal oxides such as In₂O₃ doped with Sn (ITO), SnO₂ doped with Sb, and SnO₂ doped with F (FTO) are more preferably used, and from the viewpoint of heat resistance, FTO is the most preferable. A coating amount of a material forming the first electrode to the substrate is not particularly limited, and is preferably about 1 to 100 g per 1 m² of the substrate.

A member having a first electrode formed on a substrate is also referred to as “a conductive support”.

A film thickness of the conductive support is not particularly limited, and preferably within the range from 0.1 mm to 5 mm. The surface resistance of the conductive support is preferably 50 Ω/cm² or less, and more preferably 10 Ω/cm² or less. The lower limit of the surface resistance of the conductive support is preferably as low as possible, and thus is not particularly necessarily prescribed, but a sufficient surface resistance is 0.01 Ω/cm² or more. A preferable range of light transmittance of the conductive support is the same as the preferable range of the light transmittance of the substrate as described above.

(Barrier Layer)

The photoelectric conversion element of the present invention preferably comprises as means for prevention of short circuit a barrier layer between the first electrode and the semiconductor layer which is in a membrane form (layered form).

The barrier layer and the photoelectric conversion layer are preferably porous as described below. In this case, when a porosity of the barrier layer is assumed to be C [%], and the porosity of the semiconductor layer is assumed to be D [%], D/C is preferably about 1.1 or more, for example, more preferably about 5 or more, and further more preferably about 10 or more. The upper limit of D/C is preferably as large as possible and thus is not particularly necessarily prescribed, but the upper limit of D/C is generally about 1,000 or less. Accordingly, the barrier layer and the semiconductor layer can more favorably exhibit their functions, respectively.

More specifically, the porosity C of the barrier layer is, for example, preferably about 20% or less, more preferably about 5% or less and further more preferably about 2% or less. That is, the barrier layer is preferably a dense layer. By this, the effects can be more improved. The lower limit of the porosity C of the barrier layer is preferably as small as possible and thus is not particularly necessarily prescribed, but the lower limit of the porosity C is generally about 0.05% or more.

An average thickness of the barrier layer (film thickness) is, for example, preferably about 0.01 to 10 μm, and more preferably about 0.03 to 0.5 μm. By this, the effects can be more improved.

A materials which can constitute the barrier layer is not particularly limited and, for example, one or combination of at least two of zinc, niobium, tin, titanium, vanadium, indium, tungsten, tantalum, zirconium, molybdenum, manganese, iron, copper, nickel, iridium, rhodium, chromium, ruthenium or oxides thereof, or perovskites such as strontium titanate, calcium titanate, barium titanate, magnesium titanate, and strontium niobate, or complex oxides or oxide mixtures thereof, and various metal compounds such as CdS, CdSe, TiC, Si₃N₄, SiC, and BN can be used.

Particularly when the hole transport layer is a p-type semiconductor, and a metal is used for the barrier layer, a metal having a smaller value of a work function than that of the hole transport layer and contacting in the schottky-type is preferably used. When a metal oxide is used for the barrier layer, a metal oxide which ohmically contacts with a transparent conductive layer, and has an energy level in the conduction band lower than that of the porous semiconductor layer 4 is preferably used. In this case, selection of an oxide makes it possible to improve electron transfer efficiency from the porous semiconductor layer (photoelectric conversion layer) to the barrier layer. Among these, a barrier layer having conductivity equivalent to the semiconductor layer (photoelectric conversion layer) is preferable, and particularly, a barrier layer made mainly of titanium oxide is more preferable.

(Photoelectric Conversion Layer)

The photoelectric conversion layer contains a semiconductor and a sensitizing dye, and is made of a semiconductor layer having the sensitizing dye supported on the semiconductor.

(Semiconductor)

For a semiconductor used for the semiconductor layer, examples including elemental substances such as silicon and germanium, compounds having elements from the group 3 to the group 5 and the group 13 to the group 15 in the periodic table (also referred to as periodic table of the elements), metal chalcogenides (for example, oxides, sulfides, and selenides), and metal nitrides can be used. Examples of preferable metal chalcogenide include oxides of titanium, tin, zinc, iron, tungsten, zirconium, hafnium, strontium, indium, cerium, yttrium, lanthanum, vanadium, niobium or tantalum, sulfides of cadmium, zinc, lead, silver, antimony or bismuth, selenides of cadmium or lead, and tellurides of cadmium. Examples of other compounds for the semiconductor include phosphide of zinc, gallium, indium, or cadmium, selenides of gallium-arsenic or copper-indium, sulfide of copper-indium, and nitride of titanium. Specific examples thereof include TiO₂, SnO₂, Fe₂O₃, WO₃, ZnO, Nb₂O₅, CdS, ZnS, PbS, Bi₂S₃, CdSe, CdTe, GaP, InP, GaAs, CuInS₂, CuInSe₂, and Ti₃N₄. Among them, TiO₂, ZnO, SfO₂, Fe₂O₃, WO₃, Nb₂O₅, CdS and PbS are preferably used, TiO₂ or Nb₂O₅ is more preferably used, and TiO₂ (titanium oxide) is particularly preferably used. For example, one or a combination of several kinds of the above metal oxides or metal sulfides may be used, and a titanium oxide semiconductor mixed with 20% by weight of titanium nitride (Ti₃N₄) may also be used. Alternatively, a zinc oxide/tin oxide complex, as described in J. Chem. Soc. Chem. Commun., 15 (1999), may be used for the semiconductor. In this case, when a component other than a metal oxide or a metal sulfide is added for the semiconductor, a weight ratio of the component added to the metal oxide or metal sulfide semiconductor is preferably 30% or less. The semiconductor used for the semiconductor layer may be used solely or two or more semiconductors may be used in combination.

A shape of a semiconductor used for the semiconductor layer is not particularly limited, and the semiconductor may have any shape of a spherical shape, a columnar shape, a tubular shape, or the like. A size of a semiconductor used for the semiconductor layer is also not particularly limited. For example, an average particle diameter of a semiconductor in the case that the semiconductor used for the semiconductor layer is spherical is preferably 1 to 5,000 nm, and more preferably 2 to 100 nm. The “average particle diameter” of the semiconductor used for the semiconductor layer is referred to as an average of primary particle diameters (average primary particle diameter) when 100 or more samples are observed with an electron microscope.

The semiconductor according to the present invention may be subjected to a surface treatment using an organic base. Examples of the organic base include diarylamine, triarylamine, pyridine, 4-t-butyl pyridine, polyvinyl pyridine, quinoline, piperidine, and amidine. Among them, pyridine, 4-t-butyl pyridine, and polyvinyl pyridine are preferable. The surface treatment method of a semiconductor is not particularly limited, and known methods can be used directly or suitably modified to be applied. For example, the organic base may be used directly in the case of a liquid, and a solution (an organic base solution) obtained by dissolving the organic base in an organic solvent may be prepared in the case of a solid, and the semiconductor according to the present invention is immersed in the liquid organic base or the organic base solution at 0 to 80° C. for 1 minute to 24 hours, to perform a surface treatment on the semiconductor.

<<Preparation of Semiconductor Layer>>

A method for preparing a semiconductor layer will be described.

When a semiconductor for the semiconductor layer is in a particle form, (1) a method which comprises coating or spraying a dispersion or colloidal solution of a semiconductor (semiconductor-containing coating liquid) to a conductive support, to prepare a semiconductor layer; (2) a method which comprises coating a precursor of semiconductor fine particles to a conductive support, hydrolyzing with a moisture content (for example, moisture content in the air), and thereafter performing condensation (sol-gel method), or the like can be used. The method (1) is preferable. When the semiconductor according to the present invention is in a membrane form, and is not disposed on the conductive support, the semiconductor layer is preferably prepared by laminating the semiconductor on the conductive support.

As a preferable embodiment of a method for preparing a semiconductor layer, a method which comprises forming a semiconductor layer on the conductive support by firing using fine particles of a semiconductor can be cited.

When the semiconductor according to the present invention is prepared by firing, sensitizing treatment of the semiconductor using a dye (such as adsorption and filling into a porous layer) is preferably performed after firing. After firing, an adsorption treatment of the compound is preferably quickly performed before adsorbing water to the semiconductor.

A method of forming a semiconductor layer by firing using semiconductor fine powder which is preferably used in the present invention will be specifically described below.

(Preparation of Semiconductor-Containing Coating Liquid)

Firstly, a coating liquid containing a semiconductor, preferably semiconductor fine powder (a semiconductor-containing coating liquid) is prepared. The semiconductor fine powder preferably has a primary particle diameter as small as fine as possible, and the primary particle diameter is preferably 1 to 5,000 nm, and more preferably 2 to 100 nm. The coating liquid containing semiconductor fine powder can be prepared by dispersing the semiconductor fine powder in a solvent.

The semiconductor fine powder dispersed in the solvent is dispersed in the form of primary particule. The solvent is not particularly limited as long as it can disperse the semiconductor fine powder. For the solvent, examples thereof include water, an organic solvent, and a mixed solution of water and an organic solvent. For the organic solvent, alcohols such as methanol, ethanol, and isopropanol, ketones such as methyl ethyl ketone, acetone and acetylacetone, hydrocarbons such as hexane and cyclohexane, cellulose derivatives such as acetyl cellulose, nitrocellulose, acetylbutyl cellulose, ethyl cellulose, and methyl cellulose are used. Into the coating liquid, surfactants, acids (such as acetic acid and nitric acid), viscosity modifiers (polyvalent alcohols such as polyethylene glycol), and chelating agents (such as acetylacetone) can be optionally added. A concentration of semiconductor fine powder in a solvent is preferably within the range from 0.1 to 70% by weight, and more preferably from 0.1 to 30% by weight.

(Coating of Semiconductor-Containing Coating Liquid and Firing Treatment of Formed Semiconductor Layer)

A semiconductor-containing coating liquid obtained as described above is coated or sprayed onto the conductive support, dried, then fired in the air or an inert gas, to form a semiconductor layer (also referred to as a semiconductor film) on the conductive support. Herein, a coating method is not particularly limited, and examples thereof include known methods such as a doctor blade method, a squeegee method, a spin coating method, and a screen printing method.

The film obtained by coating the semiconductor-containing coating liquid on the conductive support and drying is made of aggregation of semiconductor fine particles, and a particle diameter of the fine particle corresponds to a primary particle diameter of the semiconductor fine powder.

A semiconductor layer (semiconductor fine particle layer) formed on a conductive layer such as a conductive support generally has weak bonding force with the conductive support and weak bonding force between the fine particles, and thus has poor mechanical strength. Therefore, in order to form a semiconductor layer having increased mechanical strength and firmly adhered to a substrate, a firing treatment on the semiconductor layer (semiconductor fine particle layer) is performed.

The semiconductor layer may have any structure and preferably has a porous film (also referred to as a porous layer having voids). When the semiconductor layer is a porous film, it is preferable that components such as a hole transport substance of a hole transport layer are present also in this void. Herein, the porosity of the semiconductor layer is not particularly limited, and preferably 1 to 90% by volume, more preferably 10 to 80% by volume, and particularly preferably 20 to 70% by volume. As used herein, a porosity of a semiconductor layer is referred to as a porosity of pores which pass through in the thickness direction of a dielectric material, and can be measured using a commercially available device such as a mercury porosimeter (SHIMADZU Pore Sizer 9220 type). A film thickness of a semiconductor layer formed as a fired product film having a porous structure is not particularly limited, and preferably at least 10 nm or more, and more preferably 500 to 30,000 nm. Within such a range, a semiconductor layer excellent in characteristics such as transmittance and conversion efficiency can be formed. A semiconductor layer may be a single layer formed from semiconductor fine particles having approximately the same average particle diameters, or a multilayer film (layered structure) made from semiconductor layers containing semiconductor fine particles having different average particle diameters or of different kinds.

The firing condition is not particularly limited. From the viewpoint of suitably adjusting an actual surface area of fired film and obtaining a fired film having the above porosity at the time of the firing treatment, a firing temperature is preferably lower than 1,000° C., more preferably within the range from 200 to 800° C., and particularly preferably within the range from 300 to 800° C. In addition, in the case that a substrate is plastic, or the like, and has deteriorated heat resistance, pressurization can be applied to adhere fine particles each other or fine particles with a substrate instead of performing a firing treatment at 200° C. or more, or a semiconductor layer can be subjected only to a heat treatment with microwaves without heating a substrate. From the above viewpoint, a firing time is preferably from 10 seconds to hours, more preferably from 1 to 240 minutes, and particularly preferably from 10 to 120 minutes. A firing atmosphere is also not particularly limited, and the firing step is generally carried out in the air or an inert gas (for example, argon, helium, and nitrogen) atmosphere. The firing may be performed once at a single temperature or repeated twice or more by changing a temperature and a time.

A ratio of an actual surface area to an apparent surface area can be controlled by a particle diameter and a specific surface area of a semiconductor fine particle, a firing temperature, and the like.

For the purpose of enhancing electron injection efficiency from a dye to a semiconductor particle by increasing a surface area of a semiconductor particle or increasing a purity of a semiconductor particle periphery after the heat treatment, for example, chemical plating treatment using an aqueous titanium tetrachloride solution or an electrochemical plating treatment using an aqueous titanium trichloride solution may be performed.

(Sensitizing Treatment on Semiconductor Layer)

A total support amount of the dye in the present invention per 1 m² of the semiconductor layer is not particularly limited, and preferably within the range from 0.01 to 100 mmol, more preferably within the range from 0.1 to 50 mmol, and particularly preferably within the range from 0.5 to 20 mmol.

When a sensitizing treatment is carried out, a sensitizing dye may be used solely or plural sensitizing dyes may be used in combination, or a sensitizing dye may also be used in mixing with another compound (for example, compounds described in U.S. Pat. Nos. 4,684,537; 4,927,721; 5,084,365; 5,350,644; 5,463,057; and 5,525,440; JP-A-7-249790 and JP-A-2000-150007).

Particularly, when the photoelectric conversion element of the present invention is applied to a solar cell described later, two or more kinds of dyes having different absorption wavelengths are used by mixing so as to extend a wavelength range of photoelectric conversion as much as possible to use solar light effectively.

A method of supporting a sensitizing dye on a semiconductor is not particularly limited, and known methods can be applied in the same manner or with suitable modification. For example, to support a sensitizing dye on a semiconductor, a method of dissolving a sensitizing dye in a suitable solvent and immersing a thoroughly-dried semiconductor layer in the solution for a long time may be generally used. In a sensitizing treatment by using plural sensitizing dyes in combination or using another dye in combination, a mixed solution of respective dyes may be prepared to be used, or separate solutions of respective dyes may be prepared and a semiconductor layer can be sequentially immersed in each solution to be prepared. When separate solutions of respective sensitizing dyes are prepared and a semiconductor layer can be sequentially immersed in each solution to be prepared, the order of immersing a semiconductor with sensitizing dyes, and the like may be any order. Alternatively, semiconductor fine particles to which the dye is adsorbed solely may be mixed to prepare a semiconductor layer.

In the case of a semiconductor having a high porosity, an adsorption treatment with sensitizing dyes, and the like is preferably completed before water, water vapor, etc. is adsorbed to voids on a semiconductor layer and the inside of the semiconductor layer.

A sensitizing treatment of a semiconductor is carried out by dissolving the sensitizing dye into a suitable solvent and immersing a substrate on which a semiconductor is fired in the solution. In this treatment, air bubbles in the film are preferably removed by previously carrying out a depressurization treatment or a heat treatment on the substrate on which the semiconductor layer (also referred to as the semiconductor film) is formed by firing. Due to such a treatment, a sensitizing dye can deeply enter the inside of the semiconductor layer (semiconductor thin film), and it is particularly preferable when the semiconductor layer (semiconductor thin film) is a porous film.

A solvent used for dissolving a sensitizing dye is not particularly limited as long as it can dissolve a sensitizing dye, and does not dissolve a semiconductor nor react with a semiconductor. However, deaeration and distillation purification are preferably previously performed in order to prevent water and a gas dissolved in a solvent from entering into a semiconductor film to hinder a sensitizing treatment such as adsorption of a sensitizing dye. Examples of a solvent preferably used for dissolving a sensitizing dye include nitrile solvents such as acetonitrile, alcoholic solvents such as methanol, ethanol, n-propanol, isopropanol, and t-butyl alcohol, ketone solvents such as acetone and methyl ethyl ketone, ether solvents such as diethylether, diisopropylether, tetrahydrofuran, and 1,4-dioxane, and halogenated hydrocarbon solvents such as methylene chloride and 1,1,2-trichloroethane. These solvents may be used alone or two or more kinds may be used in mixing. Among these solvents, acetonitrile, methanol, ethanol, n-propanol, isopropanol, t-butyl alcohol, acetone, methyl ethyl ketone, tetrahydrofuran and methylene chloride, and mixed solvents thereof, for example, an acetonitrile/methanol mixed solvent, an acetonitrile/ethanol mixed solvent, and an acetonitrile/t-butylalcohol mixed solvent, are preferable.

(Temperature and Time of Sensitizing Treatment)

Conditions of the sensitizing, treatment are not particularly limited. For example, a time for immersing a substrate on which a semiconductor has been fired in a solution containing a sensitizing dye is preferable for sufficiently progressing adsorption by deeply entering a dye into the semiconductor layer (semiconductor film) to fully sensitizing the semiconductor. Further, from the viewpoint of suppressing adsorption of a dye by a decomposed substance that is generated due to decomposition, or the like of the dye in a solvent, a temperature in the sensitizing treatment is preferably 0 to 80° C., and more preferably 20 to 50° C. From the same viewpoint, a time for the sensitizing treatment is preferably 1 to 24 hours, and more preferably 2 to 6 hours. Particularly, the sensitizing treatment is performed preferably for 2 to 48 hours, and particularly preferably for 3 to 24 hours under the condition of room temperature (25° C.). The effects thereby can be significant particularly attained in the case that the semiconductor layer is a porous film. However, the immersion time is a value in the condition at 25° C., and when the temperature condition is changed, the immersion time is not limited to the above range.

In the immersion, a solution containing the dye according to the present invention may be heated up to a temperature not enough for boiling as long as the dye does not decompose. A temperature range is preferable from 5 to 100° C., and more preferably from 25 to 80° C., but is not limited thereto when the solvent boils within the above temperature range.

(Second Electrode)

The second electrode may be an electrode having conductivity and any conductive material can be used. An insulating substance can be even used when a conductive substance layer is set on the side facing to a hole transport layer. The second electrode preferably has good contact property with the hole transport layer. The second electrode preferably has a small difference in work function from the hole transport layer, and is also preferably chemically stable. Such a material is not particularly limited, and examples thereof include metal thin films of gold, silver, copper, aluminum, platinum, rhodium, magnesium, indium, conductive metal oxides (e.g., indium-tin complex oxide and fluorine-doped tin oxide), and organic conductive materials such as carbon, carbon black, conductive polymers. A thickness of the second electrode is also not particularly limited, and preferably 10 to 1,000 nm. A surface resistance of the second electrode is not particularly limited, and preferably low, and specifically, the surface resistance of the second electrode is preferably 80 Ω/cm² or less, and more preferably 20 Ω/cm² or less. The lower limit of the surface resistance of the second electrode is preferably as low as possible, and thus is not particularly necessarily prescribed, but 0.01 Ω/cm² or more is sufficient.

A method of forming the second electrode is not particularly limited, and known methods can be applied. For example, methods such as by deposition (including vacuum deposition) of the above materials for the second electrode, sputtering, coating, and screen printing are preferably used.

(Solar Cell)

The photoelectric conversion element of the present invention can be particularly preferably used in a solar cell. Therefore, the present invention also provides a solar cell which comprises the photoelectric conversion element of the present invention or a photoelectric conversion element produced by the method of the present invention.

The solar cell of the present invention comprises the photoelectric conversion element of the present invention. The solar cell of the present invention is provided with the photoelectric conversion element of the present invention, and a design and circuit design, which are the most suitable for the solar light, are attained, and the solar cell has a structure in which most suitable photoelectric conversion is performed when the solar light is used as the light source. That is, it has a structure in which the solar light is irradiated to a dye sensitized semiconductor. In forming the solar cell of the present invention, it is preferable that the photoelectric conversion layer, the hole transport layer and the second electrode are stored and sealed in a container or the entirety of them is resin-sealed.

When the solar light or electromagnetic wave equivalent to the solar light is irradiated to the solar cell of the present invention, a sensitizing dye supported on a semiconductor absorbs irradiated light or electromagnetic wave to be excited. Electrons generated due to excitation transfer to the semiconductor, and then transfer to the second, electrode through the conductive support and external load, to be supplied to a hole transport material of a hole transport layer. On the other hand, the sensitizing dye which transferred electrons to the semiconductor becomes an oxidant, but the oxidant gets back to be the original state due to reduction by supplying electrons through the polymer of the hole transport layer from the second electrode and, at the same time, the polymer of the hole transport layer is oxidized and again gets back to a state that can be reduced by electrons supplied from the second electrode. As described above, electrons flow, and a solar cell using the photoelectric conversion element of the present invention can be constituted.

### EXAMPLES

The present invention will be described in view of working examples below, and the invention is not limited thereto.

### Examples

### Preparation of Photoelectric Conversion Element SC-1 (Present Invention)

A fluorine-doped tin oxide (FTO) conductive glass substrate (coating amount of FTO: 7 g/m², thickness of first electrode: 0.9 μm, thickness of conductive support: 1.1 mm) having a surface resistance of 9Ω/□ was used as the conductive support. A film was prepared with a spin coating method by dropping a solution obtained by diluting 1.2 mL of tetrakis(isopropoxy)titanium and 0.8 mL of acetylacetone with 18 mL of ethanol on the substrate, and thereafter heating the substrate at 450° C. for 8 minutes, to form a barrier layer (porosity C, 1.0%) made of a titanium oxide thin film having a thickness of 30 to 50 nm on the transparent conductive film (FTO).

A titanium oxide paste (anatase type, average primary particle diameter (average from microscopic observation) of 18 nm, dispersed in ethyl cellulose) was coated on the FTO glass substrate on which the barrier layer was formed by a screen printing method (coating area of 25 mm²). Firing was carried out at 200° C. for 10 minutes and 500° C. for 15 minutes, to yield a titanium oxide thin film having a thickness of 2.5 μm and a porosity of 50% by volume as a semiconductor layer. A sensitizing dye D-10 was dissolved in a mixed solvent of acetonitrile:t-butyl alcohol=1:1 (volume ratio), to prepare a 5×10⁻⁴ mol/l solution. The FTO glass substrate on which titanium oxide was coated and fired was immersed in the resultant solution at room temperature (25° C.) for 3 hours to perform an adsorption treatment of a dye, and to form a photoelectric conversion layer to obtain a semiconductor electrode. The total support amount of the sensitizing dye D-10 of the present invention per 1 m² of the semiconductor layer in this treatment was 2 mmol.

The semiconductor electrode was immersed in an acetonitrile solution (electrolytic polymerization solution) containing a dimer of the monomer M1-1 that corresponds to a repeating unit of the general formula (1) in a ratio of 0.01 (mol/l), and Li[(CF₃SO₂)₂N] in a ratio of 0.1 (mol/l). In this time, the temperature of the electrolytic polymerization solution was adjusted at 25° C. The semiconductor electrode was used as a working electrode, a platinum wire was used as a counter electrode, Ag/Ag⁺(AgNO₃ 0.01 M) was used as a reference electrode, and a retention voltage was set at −0.16 V. An electric current density at initiation of electrolysis was 100 μA/cm² and the electric current density at completion was 2 μA/cm². The voltage was kept for 30 minutes while irradiating light from the direction of the semiconductor layer (using xenon lamp, light intensity of 22 mW/cm², cutting a wavelength of 430 nm or less), to form a hole transport layer on the surface of the semiconductor electrode. The resultant semiconductor electrode/hole transport layer was washed with acetonitrile and dried.

The hole transport layer thus obtained was a polymer film that is insoluble to a solvent.

Then, the resultant semiconductor electrode/hole transport layer was immersed in an acetonitrile solution containing Li[(CF₃SO₂)₂N] in a ratio of 15×10⁻³ (mol/l) and 4-tert-butylpyridine in a ratio of 50×10⁻³ (mol/l) for 10 minutes.

Subsequently, the semiconductor electrode/hole transport layer was air-dried, and 60 nm of gold was deposited by a vacuum deposition method to form a second electrode thereon to obtain a photoelectric conversion element SC-1.

[Preparation of Photoelectric Conversion Elements SC-2 to SC-14 (Present Invention)]

Photoelectric conversion elements SC-2 to SC-11 were prepared in the same manner as in preparation of the photoelectric conversion element 1, except that sensitizing dyes described in Table 1 were used instead as the sensitizing dye, and in an electrolytic polymerization solution for preparation of a hole transport layer (a layer made of a polymer having a repeating unit of the general formula (1) or general formula (2)), the monomer that corresponds to a repeating unit of the general formula (1) or general formula (2) was changed from the monomer M1-1 to monomer described in Table 1. For all monomers, polymers were synthesized in use of dimers thereof in the examples.

### Comparative Examples

### Preparation of Photoelectric Conversion Elements SC-15 to SC-19 (Comparative Examples)

Photoelectric conversion elements SC-15 to SC-19 were prepared in the same manner as in preparation of the photoelectric conversion element 1, except that sensitizing dyes described in Table 1 were used instead as the sensitizing dye, and in an electrolytic polymerization solution, the monomers described in the following Table 1 were used instead of the monomer M1-1. For all monomers, polymers were synthesized in use of dimers thereof in the examples and comparative examples. In addition, D-R1 in the following Table 1 is a sensitizing dye described below.

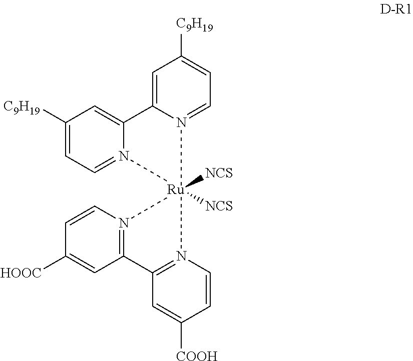

In addition, M-R1, M-R2, and M-R3 in the following Table 1 is a monomer below.

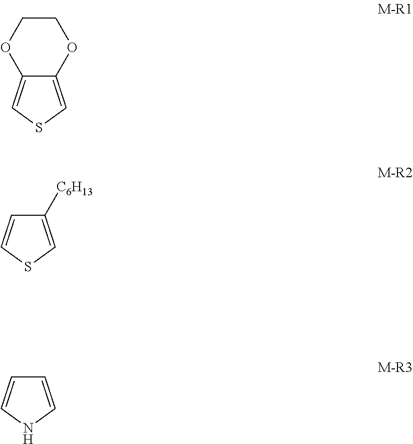

[Evaluation of Photoelectric Conversion Elements]

The photoelectric conversion elements prepared in examples and comparative examples were respectively evaluated by being irradiated with 100 mW/cm² of pseudo-solar light from a xenon lamp passed through an AM filter (AM-1.5) using a solar simulator (manufactured by EKO INSTRUMENTS Co., Ltd.). That is, for the photoelectric conversion elements, electric current-voltage was measured at room temperature using an I-V tester, to find short circuit current (Jsc), open circuit voltage (Voc), and Fill factor (F.F.), thereby obtaining photoelectric conversion efficiency (η (i)). The conversion efficiency (η (%)) of the photoelectric conversion element was calculated based on the following formula (A):

η=100×(Voc×Jsc×F.F.)/P Formula (A):

In the formula (A), P represents incident light intensity [mW/cm⁻²], Voc represents open circuit voltage [V], Jsc represents short circuit current density [mA·cm⁻²], and F.F. represents Fill factor.

(Measurement of Photoelectric Conversion Efficiency after Photodegradation Test)

After irradiating xenon lamp light having an intensity of 100 mW/cm² in an open circuit state for 3 hours, photoelectric conversion efficiency (η (%)) was determined, and a ratio (%) to the initial photoelectric conversion efficiency was calculated.

(Evaluation of Light Absorption of Hole Transport Material)

An evaluation sample for light absorption of a hole transport material was prepared in the same manner as in the above preparation method of a semiconductor electrode, except that an area of a titanium oxide film was 10×20 mm² and a thickness was 1.0 to 1.2 μm. Absorbances before and after electrolytic polymerization were measured using a spectrophotometer (JASCO V-530), and to determine a difference between the absorbances before and after electrolytic polymerization to derive an absorbance only for the polymer A. The average absorbance from 400 to 700 nm was used to be regarded as a value of light absorption of a hole transport material. In order to correct variation of film thicknesses of titanium oxide films, a value obtained by dividing the absorbance with the average film thickness (μm) of the titanium oxide film was used for comparison of absorbance.

Evaluation results of respective photoelectric conversion elements are shown in Table 1.

TABLE 1

| | | | | | | Photoelectric conversion efficiencies of photoelectric | | | | |
|---|---|---|---|---|---|---|---|---|---|---|
| | | | Short | Open | | conversion elements (η(%)) | | | | |
| Photoelectric | | | circuit | circuit | | Before | After | Ratio of efficiency | | Film thicknesses of |
| conversion | | | current | voltage | Fill | photodegradation | photodegradation | before and after | | semiconductor layer |
| element | Dye | *1 | (mA · cm⁻²) | (mV) | factor | (%) | (%) | light degradation | *2 | (μm) |
| SC-1 | D-10 | M1-1 | 4.75 | 941 | 0.55 | 2.45 | 1.68 | 0.69 | 0.83 | 3.05 |
| SC-2 | D-6 | M1-2 | 6.67 | 841 | 0.57 | 3.20 | 2.34 | 0.73 | 0.41 | 2.87 |
| SC-3 | D-6 | M1-3 | 7.30 | 868 | 0.60 | 3.80 | 3.06 | 0.81 | 0.33 | 2.78 |
| SC-4 | D-10 | M1-4 | 8.46 | 888 | 0.58 | 4.36 | 3.31 | 0.76 | 0.26 | 3.01 |
| SC-5 | D-34 | M1-4 | 8.98 | 769 | 0.60 | 4.16 | 3.22 | 0.77 | 0.27 | 2.98 |
| SC-6 | D-37 | M1-4 | 10.22 | 730 | 0.56 | 4.18 | 2.56 | 0.61 | 0.29 | 3.11 |
| SC-7 | D-30 | M1-5 | 8.25 | 810 | 0.63 | 4.21 | 3.11 | 0.74 | 0.33 | 3.04 |
| SC-8 | D-22 | M1-6 | 6.02 | 765 | 0.56 | 2.58 | 1.62 | 0.63 | 0.30 | 2.90 |
| SC-9 | D-41 | M1-13 | 6.44 | 836 | 0.53 | 2.85 | 2.00 | 0.70 | 0.44 | 3.07 |
| SC-10 | D-6 | M1-16 | 5.51 | 850 | 0.53 | 2.48 | 1.68 | 0.68 | 0.66 | 2.80 |
| SC-11 | D-6 | M2-1 | 6.43 | 822 | 0.60 | 3.17 | 2.48 | 0.78 | 0.38 | 2.63 |
| SC-12 | D-6 | M2-2 | 7.92 | 904 | 0.59 | 4.22 | 3.16 | 0.75 | 0.24 | 3.13 |
| SC-13 | D-10 | M2-2 | 9.82 | 841 | 0.60 | 4.96 | 3.71 | 0.75 | 0.26 | 2.95 |
| SC-14 | D-6 | M2-7 | 5.54 | 810 | 0.54 | 2.42 | 1.71 | 0.71 | 0.48 | 3.11 |
| SC-15 | D-6 | M-R1 | 4.40 | 825 | 0.50 | 1.92 | 0.97 | 0.51 | 1.27 | 2.88 |
| SC-16 | D-6 | M-R2 | 4.81 | 699 | 0.48 | 1.61 | 0.72 | 0.45 | 3.55 | 2.86 |
| SC-17 | D-6 | M-R3 | 1.15 | 707 | 0.53 | 0.43 | 0.18 | 0.42 | 4.60 | 2.98 |
| SC-18 | D-R1 | M1-3 | 2.65 | 772 | 0.65 | 1.33 | 0.65 | 0.49 | 0.36 | 2.87 |
| SC-19 | D-R1 | M1-3 | 4.09 | 813 | 0.63 | 2.09 | 1.14 | 0.55 | 0.34 | 9.79 |

*1: Monomer corresponding to a repeating unit (1) or (2) of the general formula (1) or (2)
*2: Absorbance of a polymer having a repeating unit (1) or (2) of the general formula (1) or (2)

It is noted from Table 1 that the photoelectric conversion elements (SC-1 to SC-14) of the present invention comprising the hole transport layer containing the polymer according to the present invention and the sensitizing dye according to the present invention have a semiconductor layer with a film thickness of only about 3 μm, and thus the absorbance of the polymer having a repeating unit of the general formula (1) or general formula (2) can be decreased. Therefore, the photoelectric conversion elements (SC-1 to SC-14) of the present invention have high photoelectric conversion efficiencies and also are excellent in stability thereof. In particular, the photoelectric conversion element containing a polymer having the repeating unit (1) of the general formula (1) in which R is a linear alkyl group having 6 to 18 carbon atoms or a polymer having a repeating unit of the general formula (2) in which n is 1 shows more excellent photoelectric conversion efficiency. Further, when a sensitizing dye has two acidic groups, durability is improved as compared with the case of not having two acidic groups. On the other hand, in the photoelectric conversion elements (SC-15 to SC-19) of comparative examples, photoelectric conversion elements (SC-15, SC-16, SC-17) comprising a hole transport layer containing polymers that is not involved in the scope of the present invention have large absorbance even when the sensitizing dye according to the present invention is used. Therefore, these photoelectric conversion element have low photoelectric conversion efficiency and also are inferior in stability thereof. Additionally, it is noted that, in photoelectric conversion elements (SC-18, SC-19) using a ruthenium complex as a sensitizing dye, light absorption of a dye is not sufficient with a film thickness of 3 μm, and thus, photoelectric conversion efficiency is low (SC-18), while when a film thickness is made as large as 10 μm (SC-19), photoelectric conversion efficiency is not sufficiently increased due to influence of absorption of a hole transport layer.

According to the above results, it can be presumed that by combined effects by a hole transport layer containing the polymer according to the present invention and the sensitizing dye according to the present invention, light absorption of the hole transport layer is decreased, and light excitation in the hole transport layer is also decreased, which leads to improvement in durability due to suppressed degradation of the hole transport layer.

What is claimed is:

1. A photoelectric conversion element comprising a substrate, a first electrode, a photoelectric conversion layer containing a semiconductor and a sensitizing dye, and a hole transport layer, and a second electrode,
wherein said hole transport layer comprises a polymer having a repeating unit (1) represented by the following general formula (1): 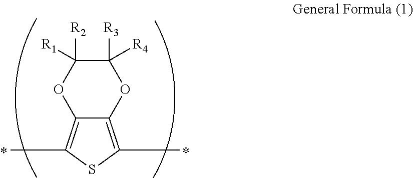
wherein R₁ to R₄ each independently represent a hydrogen atom, a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, provided that at least one of R₁ to R₄ is a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, and the remaining substituents are hydrogen atoms,
or a repeating unit (2) represented by the following general formula (2): 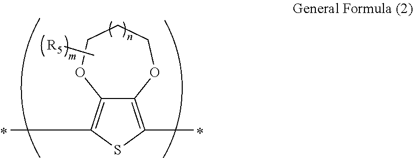
wherein R₅ each independently represents a halogen atom, a linear or branched alkyl group having 1 to 24 carbon atoms, or an alkoxy group having 1 to 18 carbon atoms, n is an integer from 1 to 3, and m is an integer from 0 to 2n+4, and
said sensitizing dye is represented by the following general formula (3A), (3B) or (3C): 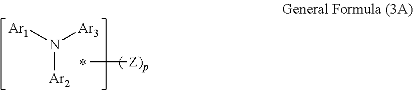
wherein Ar₁ to Ar₃ each independently represent an aromatic group, provided that any two of Ar₁ to Ar₃ may bond each other to form a ring structure, Z represents a group having an acidic group and an electron-attracting group or a group having an acidic group and an electron-attracting ring structure, which is substituted in any of Ar₁ to Arₐ, and p is an integer from 1 to 3, 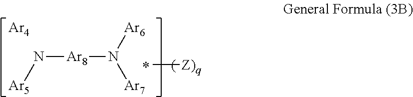
wherein Ar₄ to Ar₇ each independently represent an aromatic group, provided that Ar₄ and Ar₅ or Ar₆ and Ar₇ may bond each other to form a ring structure, Ar₈ represents a divalent aromatic group, Z represents a group having an acidic group and an electron-attracting group or a group having an acidic group and an electron-attracting ring structure, which is substituted in any of Ar₄ to Ar₇, and q is an integer from 1 to 4, 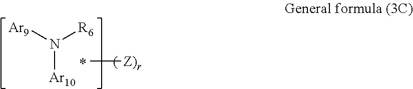
wherein Ar₉ and Ar₁₀ each independently represent an aromatic group, R₆ represents a linear or branched alkyl group having 1 to 24 carbon atoms, or a cycloalkyl group having 3 to 9 carbon atoms, provided that Ar₉ and Ar₁₀, or Ar₉ or Ar₁₀ and R₆ may bond each other to form a ring structure, Z represents a group having an acidic group and an electron-attracting group or a group having an acidic group and an electron-attracting ring structure, which is substituted in any of Ar₉, Ar₁₀ and R₆, and r is an integer of 1 to 2.

2. The photoelectric conversion element according to claim 1, wherein the polymer having the repeating unit represented by the general formula (1) or (2) has an average absorbance in a wavelength region from 400 to 700 nm of 0.2 to 1.0.

3. The photoelectric conversion element according to claim 1, wherein the sensitizing dye has two acidic groups.

4. The photoelectric conversion element according to claim 1, wherein the semiconductor is titanium oxide.

5. The photoelectric conversion element according to claim 1, wherein, in the general formula (1), at least one of R₁ to R₄ is a linear alkyl group having 6 to 18 carbon atoms, or in the general formula (2), n is 1.

6. The photoelectric conversion element according to claim 1, wherein, in the general formula (1), R₁ is a linear alkyl group having 6 to 18 carbon atoms, and R₂, R₃ and R₄ are a hydrogen atom.

7. The photoelectric conversion element according to claim 1, wherein, in the general formula (3A), (3B) or (3C), the acidic group in Z is a carboxyl group, a sulfo group, a phosphonic acid group, or a hydroxy group.

8. The photoelectric conversion element according to claim 1, wherein, in the general formula (3A), (3B) or (3C), the acidic group in Z is a carboxyl group, a sulfo group, or a phosphonic acid group.

9. The photoelectric conversion element according to claim 1, wherein, in the general formula (3A), (3B) or (3C), the electron-attracting group in Z is a cyano group, a nitro group, a fluoro group, or a chloro group.

10. The photoelectric conversion element according to claim 1, wherein, in the general formula (3A), (3B) or (3C), the electron-attracting group in Z is a cyano group or a nitro group.

11. The photoelectric conversion element according to claim 1, wherein, in the general formula (3A), (3B) or (3C), the electron-attracting ring structure in Z is a rhodanine ring, a dirhodanine ring, an imidazolone ring, a pyrazoline ring, a quinone ring, or a thiadiazole ring.

12. The photoelectric conversion element according to claim 1, wherein, in the general formula (3A), (3B) or (3C), the electron-attracting ring structure in Z is a rhodanine ring, a dirhodanine ring, an imidazolone ring, or a pyrazoline ring.

13. The photoelectric conversion element according to claim 1, wherein the hole transport layer comprises a polymer having a repeating unit (1) represented by the following general formula (1), and the sensitizing dye is represented by the general formula (3A).

14. The photoelectric conversion element according to claim 1, wherein the sensitizing dye is represented by the following general formula (3D): 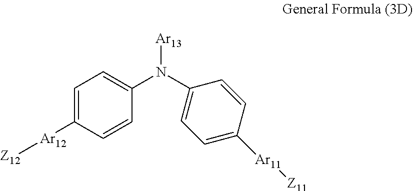
wherein Ar₁₁ and Ar₁₂ each independently represent a divalent aromatic group, Ar₁₃ represents an aromatic group, and, Z₁₁ and Z₁₂ each independently represent a group having an acidic group and an electron-attracting group or a group having an acidic group and an electron-attracting ring structure.

15. The photoelectric conversion element according to claim 14, wherein, in the general formula (3D), Ar₁₁ and Ar₁₂ comprise a thiophene ring.

16. A method for producing a photoelectric conversion element according to claim 1, comprising a substrate, a first electrode, a photoelectric conversion layer containing a semiconductor and a sensitizing dye, a hole transport layer, and a second electrode,
wherein said hole transport layer is formed by electrolytic polymerization using a monomer (1) represented by the following general formula (1′): 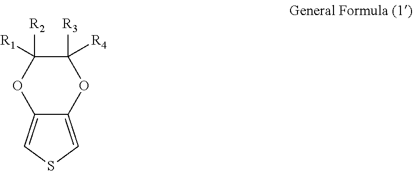
wherein R₁ to R₄ each independently represent a hydrogen atom, a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, provided that at least one of R₁ to R₄ is a linear or branched alkyl group having 1 to 24 carbon atoms, a cycloalkyl group having 3 to 9 carbon atoms, an alkoxy group having 1 to 18 carbon atoms, a polyethylene oxide group having 2 to 18 carbon atoms, or an aryl group, and the remaining substituents are hydrogen atoms,
or a monomer (2) represented by the following general formula (2′): 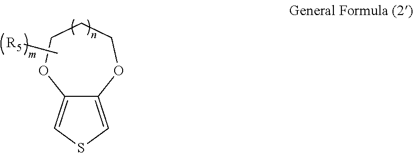
wherein R₅ each independently represents a halogen atom, a linear or branched alkyl group having 1 to 24 carbon atoms, or an alkoxy group having 1 to 18 carbon atoms, n is an integer from 1 to 3, and m is an integer from 0 to 2n+4,
or a multimer thereof.

17. The method for producing a photoelectric conversion element according to claim 16, wherein the electrolytic polymerization of the monomer (1), monomer (2) or multimer thereof is carried out on the photoelectric conversion layer.

18. A solar cell, comprising the photoelectric conversion element set forth in claim 1.
